(19) United States
(12) Patent Application Publication
(10) Pub. No.: US 2024/0427246 A1
(43) Pub. Date: Dec. 26, 2024

(54) RESIST UNDERLAYER FILM-FORMING COMPOSITION CONTAINING TERMINATED POLYMER

(71) Applicant: NISSAN CHEMICAL CORPORATION, Tokyo (JP)

(72) Inventors: Tomotada HIROHARA, Toyama-shi (JP); Hiroto OGATA, Toyama-shi (JP)

(73) Assignee: NISSAN CHEMICAL CORPORATION, Tokyo (JP)

(21) Appl. No.: 18/719,010

(22) PCT Filed: Jan. 24, 2023
(86) PCT No.: PCT/JP2023/002000

§ 371 Date: Jun. 12, 2024

(30) Foreign Application Priority Data
Jan. 25, 2022 (JP) 2022-009157

(51) Int. Cl. G03F 7/11; C08G 59/26; C08G 59/40; C08G 59/62; G03F 7/00; G03F 7/16; H01L 21/311

(52) U.S. Cl. CPC G03F 7/11; C08G 59/26; C08G 59/4042; C08G 59/621; G03F 7/168; G03F 7/70033; H01L 21/31144

(57) ABSTRACT

A composition for forming a resist underlayer film in which a desired resist pattern can be formed, a method for manufacturing a resist pattern using said composition for forming a resist underlayer film, and a method for manufacturing a semiconductor device. The composition for forming a resist underlayer film includes an organic solvent and a polymer, the polymer containing, at the terminal, a non-cyclic aliphatic hydrocarbon group that may be interrupted by a group including a heteroatom and that may be substituted by a substitution group.

### TECHNICAL FIELD

The present invention relates to a composition that is used in a lithography process, particularly, in the most advanced (ArF, EUV, EB, or the like) lithography process in semiconductor manufacturing. The present invention also relates to an application of the resist underlayer film to a method for manufacturing a substrate with a resist pattern and to a method for manufacturing a semiconductor device.

### BACKGROUND ART

Fine processing by lithography using a resist composition has conventionally been performed in the manufacture of semiconductor devices. The fine processing is a processing method comprising forming a thin film of a photoresist composition on a semiconductor substrate such as a silicon wafer, irradiating the thin film with an active ray such as an ultraviolet ray via a mask pattern on which a device pattern has been drawn, developing the thin film, and etching the substrate with an obtained photoresist pattern as a protective film to form fine irregularities corresponding to the pattern on the substrate surface. In recent years, the degree of integration of semiconductor devices has increased, and as the active ray used, EUV light (13.5 nm wavelength) or electron beam (EB) has been considered for practical use in the most advanced fine processing in addition to the conventionally used active ray such as i-ray (365 nm wavelength), KrF excimer laser (248 nm wavelength), and ArF excimer laser (193 nm wavelength). As a result, irregular reflection and standing waves of the active ray by the semiconductor substrate have caused serious problems. Accordingly, to mitigate such problems, a method of providing a bottom anti-reflective coating (BARC) between a resist and a semiconductor substrate has been widely studied. The bottom anti-reflective coating is also referred to as a resist underlayer film. As such a bottom anti-reflective coating, an organic bottom anti-reflective coating made of a polymer or the like having a light absorption portion has been extensively studied for such a reason as ease of use.

Patent Literature 1 discloses a resist underlayer film-forming composition that is used in a lithography process for manufacturing a semiconductor device, the composition containing a polymer that contains a repeating unit structure having a polycyclic aliphatic ring in a main chain of the polymer. Patent Literature 2 discloses a resist underlayer film-forming composition for lithography containing a polymer having a specific structure at a terminal thereof.

### CITATION LIST

### Patent Literature

Patent Literature 1: JP 2009-093162 A
Patent Literature 2: WO 2013/141015 A

### SUMMARY OF INVENTION

### Technical Problem

An example of the properties required for a resist underlayer film is that the resist underlayer film is not intermixed with a resist film formed on an upper layer (is insoluble in a resist solvent).

For lithography with EUV exposure, a line width of a resist pattern to be formed is not more than 32 nm, and a resist underlayer film for EUV exposure is formed to be thinner than that in the related art for use. In forming such a thin film, pinholes, aggregations, and the like are likely to occur due to the influence of the substrate surface, the polymer to be used, and the like, and there is a difficulty in forming a uniform film with no defects.

If the polymer itself is given a high photocuring property, it is beneficial from the viewpoint of resources and environments, because use of a photoacid generator may be omitted, for example.

Furthermore, it has been required to suppress deterioration of line width roughness (LWR) in forming the resist pattern, to form a resist pattern having a satisfactory rectangular shape, and to improve resist sensitivity.

An object of the present invention is to provide a composition for forming a resist underlayer film which solves the above-mentioned problems and enables formation of a desired resist pattern, as well as a method for forming a resist pattern using the resist underlayer film-forming composition.

### Solution to Problem

The present invention includes the following.
[1]

A resist underlayer film-forming composition comprising: an organic solvent; and a polymer,
wherein the polymer has an acyclic aliphatic hydrocarbon group at a terminal, the acyclic aliphatic hydrocarbon group being optionally interrupted by a group containing a heteroatom or being optionally substituted with a substituent.
[2]

The resist underlayer film-forming composition according to [1],
wherein the acyclic aliphatic hydrocarbon group is an acyclic aliphatic hydrocarbon group having less than 12 carbon atoms.
[3]

The resist underlayer film-forming composition according to [1] or [2],
wherein the acyclic aliphatic hydrocarbon group contains at least one unsaturated carbon-carbon bond.
[4]

The resist underlayer film-forming composition according to any one of [1] to [3],
wherein the group containing the heteroatom is at least one member selected from the group consisting of an ether group, a thioether group, a carbonyl group, a thiocarbonyl group, an ester group, a thioester group, a thionoester group, an amide group, a urea group, and an oxysulfonyl group.
[5]

The resist underlayer film-forming composition according to any one of [1] to [4],
wherein the substituent is at least one member selected from the group consisting of a hydroxy group, a carboxy group, and a linear or branched alkyl, alkoxy, or acyloxy group having carbon atoms not more than 10.
[6 ]

The resist underlayer film-forming composition according to any one of [1] to [5],
wherein the polymer has at least one structural unit represented by Formula (3) in a main chain.

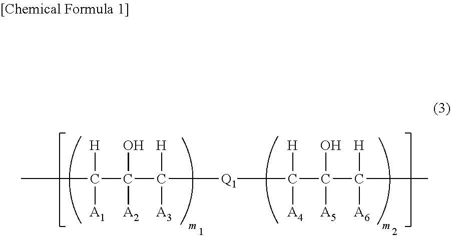

(In Formula (3), A₁, A₂, A₃, A₄, A₅, and A₆ each independently represent a hydrogen atom, a methyl group, or an ethyl group; Q₁ represents a divalent organic group; and m₁ and m₂ each independently represent 0 or 1.)
[7]

The resist underlayer film-forming composition according to [6],
wherein, Q₁ in Formula (3) represents a divalent organic group represented by Formula (5).

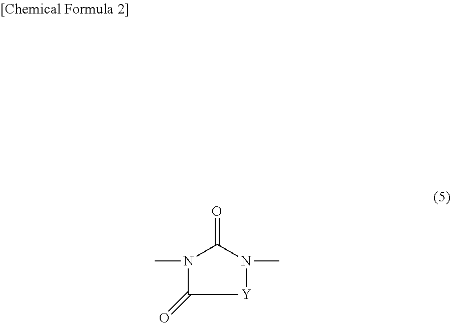

(wherein, in the formula, Y represents a divalent group represented by Formula (6) or Formula (7).)

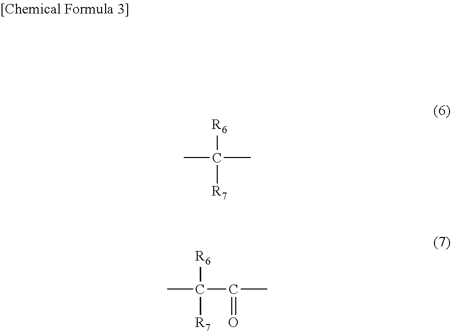

(wherein, in the formulas, R₆ and R₇ each independently represent a hydrogen atom, an alkyl group having 1 to 6 carbon atoms, an alkenyl group having 3 to 6 carbon atoms, a benzyl group, or a phenyl group, the phenyl group being optionally substituted with at least one member selected from the group consisting of an alkyl group having 1 to 6 carbon atoms, a halogen atom, an alkoxy group having 1 to 6 carbon atoms, a nitro group, a cyano group, and an alkylthio group having 1 to 6 carbon atoms, or R₆ and R₇ are optionally bonded to each other to form a ring having 3 to 6 carbon atoms together with the carbon atom to which R₆ and R₇ are bonded.)
[8]

The resist underlayer film-forming composition according to any one of [1] to [7], wherein the polymer further contains a disulfide bond in a main chain.
[9]

The resist underlayer film-forming composition according to any one of [1] to [8], further comprising a curing catalyst.
[10]

The resist underlayer film-forming composition according to any one of [1] to [9], further comprising a crosslinking agent.
[11]

A resist underlayer film, which is a baked product of a coating film of the resist underlayer film-forming composition according to any one of [1] to [10].
[12 ]

A method for manufacturing a patterned substrate, the method including the steps of: applying the resist underlayer film-forming composition according to any one of [1] to [10] onto a semiconductor substrate and baking the resist underlayer film-forming composition to form a resist underlayer film; applying a resist on the resist underlayer film and baking the resist to form a resist film; exposing the semiconductor substrate coated with the resist underlayer film and the resist; and developing the exposed resist film and performing patterning.
[13]

A method for manufacturing a semiconductor device, the method comprising the steps of:
forming a resist underlayer film of the resist underlayer film-forming composition according to any one of [1] to [10] on a semiconductor substrate;
forming a resist film on the resist underlayer film;
forming a resist pattern by irradiation of the resist film with a light or electron beam and development that follows;
forming a patterned resist underlayer film by etching the resist underlayer film via the formed resist pattern; and
processing the semiconductor substrate by the patterned resist underlayer film.

### Advantageous Effects of Invention

The resist underlayer film-forming composition for lithography of the present invention is a composition, in which the polymer contained in the resist underlayer film-forming composition has an acyclic aliphatic hydrocarbon group at the terminal, the polymer being optionally interrupted by a group containing a heteroatom or being optionally substituted with a substituent; and it is a composition comprising such a polymer and an organic solvent, and preferably further contains a crosslinking agent and/or a compound for promoting a crosslinking reaction (curing catalyst). Attributable to such technical features, the resist underlayer film-forming composition for lithography of the present application permits forming a resist pattern having a satisfactory rectangular shape (without pattern collapse), and suppressing deterioration of LWR and improving sensitivity in forming the resist pattern.

### DESCRIPTION OF EMBODIMENTS

### <Resist Underlayer Film-Forming Composition>

The resist underlayer film-forming composition of the present application contains an organic solvent and a polymer, in which the polymer has an acyclic aliphatic hydrocarbon group at a terminal, the acyclic aliphatic hydrocarbon group being optionally interrupted by a group containing a heteroatom or being optionally substituted with a substituent.

The acyclic aliphatic hydrocarbon group refers a linear or branched alkyl group, a linear or branched alkenyl group, a linear or branched alkynyl group, and any combination thereof. The number of carbon atoms of the acyclic aliphatic hydrocarbon group is preferably less than 12, and more preferably less than 10.

Examples of the alkyl group include a methyl group, an ethyl group, an n-propyl group, an i-propyl group, a cyclopropyl group, an n-butyl group, an i-butyl group, an s-butyl group, a t-butyl group, a cyclobutyl group, a 1-methyl-cyclopropyl group, a 2-methyl-cyclopropyl group, an n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, an n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, a 1-ethyl-2-methyl-n-propyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, a 2-ethyl-3-methyl-cyclopropyl group, a decyl group, an undecyl group, a dodecyl group, a tridecyl group, a tetradecyl group, a pentadecyl group, a hexadecyl group, a heptadecyl group, an octadecyl group, a nonadecyl group, and an icodecyl group.

Examples of the alkenyl group include a 1-propenyl group, a 2-propenyl group, a 1-methyl-1-ethenyl group, a 1-butenyl group, a 2-butenyl group, a 3-butenyl group, a 2-methyl-1-propenyl group, a 2-methyl-2-propenyl group, a 1-ethylethenyl group, a 1-methyl-1-propenyl group, a 1-methyl-2-propenyl group, a 1-pentenyl group, a 2-pentenyl group, a 3-pentenyl group, a 4-pentenyl group, a 1-n-propylethenyl group, a 1-methyl-1-butenyl group, a 1-methyl-2-butenyl group, a 1-methyl-3-butenyl group, a 2-ethyl-2-propenyl group, a 2-methyl-1-butenyl group, a 2-methyl-2-butenyl group, a 2-methyl-3-butenyl group, a 3-methyl-1-butenyl group, a 3-methyl-2-butenyl group, a 3-methyl-3-butenyl group, a 1,1-dimethyl-2-propenyl group, a 1-i-propylethenyl group, a 1,2-dimethyl-1-propenyl group, a 1,2-dimethyl-2-propenyl group, a 1-cyclopentenyl group, a 2-cyclopentenyl group, a 3-cyclopentenyl group, a 1-hexenyl group, a 2-hexenyl group, a 3-hexenyl group, a 4-hexenyl group, a 5-hexenyl group, a 1-methyl-1-pentenyl group, a 1-methyl-2-pentenyl group, a 1-methyl-3-pentenyl group, a 1-methyl-4-pentenyl group, a 1-n-butylethenyl group, a 2-methyl-1-pentenyl group, a 2-methyl-2-pentenyl group, a 2-methyl-3-pentenyl group, a 2-methyl-4-pentenyl group, a 2-n-propyl-2-propenyl group, a 3-methyl-1-pentenyl group, a 3-methyl-2-pentenyl group, a 3-methyl-3-pentenyl group, a 3-methyl-4-pentenyl group, a 3-ethyl-3-butenyl group, a 4-methyl-1-pentenyl group, a 4-methyl-2-pentenyl group, a 4-methyl-3-pentenyl group, a 4-methyl-4-pentenyl group, a 1,1-dimethyl-2-butenyl group, a 1,1-dimethyl-3-butenyl group, a 1,2-dimethyl-1-butenyl group, a 1,2-dimethyl-2-butenyl group, a 1,2-dimethyl-3-butenyl group, a 1-methyl-2-ethyl-2-propenyl group, a 1-s-butylethenyl group, a 1,3-dimethyl-1-butenyl group, a 1,3-dimethyl-2-butenyl group, a 1,3-dimethyl-3-butenyl group, a 1-i-butylethenyl group, a 2,2-dimethyl-3-butenyl group, a 2,3-dimethyl-1-butenyl group, a 2,3-dimethyl-2-butenyl group, a 2,3-dimethyl-3-butenyl group, a 2-i-propyl-2-propenyl group, a 3,3-dimethyl-1-butenyl group, a 1-ethyl-1-butenyl group, a 1-ethyl-2-butenyl group, a 1-ethyl-3-butenyl group, a 1-n-propyl-1-propenyl group, a 1-n-propyl-2-propenyl group, a 2-ethyl-1-butenyl group, a 2-ethyl-2-butenyl group, a 2-ethyl-3-butenyl group, a 1,1,2-trimethyl-2-propenyl group, a 1-t-butylethenyl group, a 1-methyl-1-ethyl-2-propenyl group, a 1-ethyl-2-methyl-1-propenyl group, a 1-ethyl-2-methyl-2-propenyl group, a 1-i-propyl-1-propenyl group, a 1-i-propyl-2-propenyl group, a 1-methyl-2-cyclopentenyl group, a 1-methyl-3-cyclopentenyl group, a 2-methyl-1-cyclopentenyl group, a 2-methyl-2-cyclopentenyl group, a 2-methyl-3-cyclopentenyl group, a 2-methyl-4-cyclopentenyl group, a 2-methyl-5-cyclopentenyl group, a 2-methylene-cyclopentyl group, a 3-methyl-1-cyclopentenyl group, a 3-methyl-2-cyclopentenyl group, a 3-methyl-3-cyclopentenyl group, a 3-methyl-4-cyclopentenyl group, a 3-methyl-5-cyclopentenyl group, a 3-methylene-cyclopentyl group, a 1-cyclohexenyl group, a 2-cyclohexenyl group, and a 3-cyclohexenyl group.

Examples of the alkynyl group include an ethynyl group, a 1-propynyl group, and a 2-propynyl group.

The heteroatom is not particularly limited, but is usually an oxygen atom, a sulfur atom, or a nitrogen atom.

Examples of the group containing the heteroatom include an ether group, a thioether group, a carbonyl group, a thiocarbonyl group, an ester group, a thioester group, a thionoester group, an amide group, a urea group, and an oxysulfonyl group.

The phrase “optionally interrupted by the group containing the heteroatom” means that one or two or more of an ether bond, a thioether bond, a carbonyl bond, a thiocarbonyl bond, an ester bond, a thioester bond, a thionoester bond, an amide bond, a urea bond, an oxysulfonyl bond, or the like may be included between carbon-carbon bonds of the acyclic aliphatic hydrocarbon group according to the present application. When two or more bonds are included, the bonds may be the same single kind or two or more different kinds.

Specific examples of the group containing the heteroatom that interrupts the acyclic aliphatic hydrocarbon group are as represented by the following formulas. In the formulas, * represents a bond.

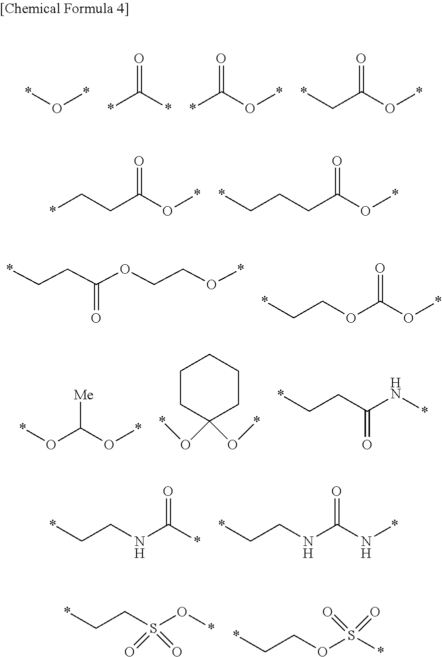

The phrase “optionally substituted with the substituent” means that all or part of hydrogen atoms of the acyclic aliphatic hydrocarbon group according to the present application may be substituted with at least one substituent selected from the group consisting of a hydroxy group, a carboxy group, and a linear or branched alkyl group having 1 to 10 carbon atoms, alkoxy group having 1 to 20 carbon atoms, or acyloxy group having 1 to 10 carbon atoms.

The alkyl group is as mentioned above.

Examples of the alkoxy group include a methoxy group, an ethoxy group, an n-propoxy group, an i-propoxy group, an n-butoxy group, an i-butoxy group, an s-butoxy group, a t-butoxy group, an n-pentyloxy group, a 1-methyl-n-butoxy group, a 2-methyl-n-butoxy group, a 3-methyl-n-butoxy group, a 1,1-dimethyl-n-propoxy group, a 1,2-dimethyl-n-propoxy group, a 2,2-dimethyl-n-propoxy group, a 1-ethyl-n-propoxy group, an n-hexyloxy group, a 1-methyl-n-pentyloxy group, a 2-methyl-n-pentyloxy group, a 3-methyl-n-pentyloxy group, a 4-methyl-n-pentyloxy group, a 1,1-dimethyl-n-butoxy group, a 1,2-dimethyl-n-butoxy group, a 1,3-dimethyl-n-butoxy group, a 2,2-dimethyl-n-butoxy group, a 2,3-dimethyl-n-butoxy group, a 3,3-dimethyl-n-butoxy group, a 1-ethyl-n-butoxy group, a 2-ethyl-n-butoxy group, a 1,1,2-trimethyl-n-propoxy group, a 1,2,2-trimethyl-n-propoxy group, a 1-ethyl-1-methyl-n-propoxy group, a 1-ethyl-2-methyl-n-propoxy group, a cyclopentyloxy group, a cyclohexyloxy group, a norbornioxy group, an adamantyloxy group, an adamantanemethyloxy group, an adamantaneethyloxy group, a tetracyclodecanyloxy group, and a tricyclodecanyloxy group.

The acyloxy group is represented by Formula (20) below.

[Chemical Formula 5]

Z—COO—* Formula (20)
(In Formula (20), Z represents a hydrogen atom or an alkyl group having 1 to 9 carbon atoms out of the alkyl groups mentioned above; and * represents a bond to the acyclic aliphatic hydrocarbon group.)

An acyclic aliphatic hydrocarbon group that contains a heteroatom and has less than 12 carbon atoms is preferable, an acyclic aliphatic hydrocarbon group that contains an oxygen atom and has less than 12 carbon atoms is more preferable, an acyclic aliphatic hydrocarbon group that is interrupted by at least two members selected from the group consisting of an ether group, a carbonyl group, and an ester group and has less than 12 carbon atoms is further preferable, and an acyclic aliphatic hydrocarbon group that is interrupted by an ether group and an ester group and has less than 12 carbon atoms is most preferable.

The acyclic aliphatic hydrocarbon group preferably has at least one unsaturated bond (for example, a double bond or a triple bond). The acyclic aliphatic hydrocarbon group preferably has one to three unsaturated bonds. The unsaturated bond is preferably a double bond.

“The acyclic aliphatic hydrocarbon group being optionally interrupted by the group containing the heteroatom or being optionally substituted with the substituent” may be induced by allowing a saturated or unsaturated dicarboxylic anhydride such as oxalic acid, malonic acid, succinic acid, glutaric acid, adipic acid, pimelic acid, suberic acid, azelaic acid, sebacic acid, maleic acid, methylmaleic acid, ethylmaleic acid, dimethylmaleic acid, or a citraconic acid to react with the terminal of the polymer by a method known per se.

The polymer preferably has at least one structural unit represented by Formula (3) below in a main chain.

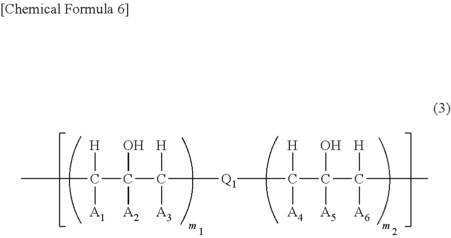

(In Formula (3), A₁, A₂, A₃, A₄, A₅, and A₆ each independently represent a hydrogen atom, a methyl group, or an ethyl group; Q₁ represents a divalent organic group; and m₁ and m₂ each independently represent 0 or 1.)

In Formula (3), Q₁ preferably represents a divalent organic group represented by Formula (5).

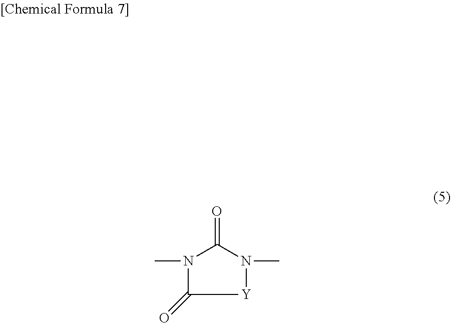

(In the formula, Y represents a divalent group represented by Formula (6) or Formula (7).)

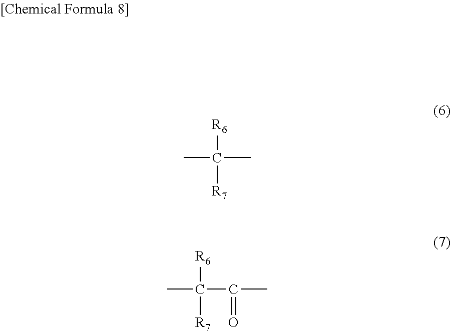

(In the formulas, R₆ and R₇ each independently represent a hydrogen atom, an alkyl group having 1 to 6 carbon atoms, an alkenyl group having 3 to 6 carbon atoms, a benzyl group, or a phenyl group, the phenyl group being optionally substituted with at least one member selected from the group consisting of an alkyl group having 1 to 6 carbon atoms, a halogen atom, an alkoxy group having 1 to 6 carbon atoms, a nitro group, a cyano group, and an alkylthio group having 1 to 6 carbon atoms, or R₆ and R₇ are optionally bonded to each other to form a ring having 3 to 6 carbon atoms together with the carbon atom to which R₆ and R₇ are bonded.)

The alkyl group, the alkenyl group, and the alkoxy group are as mentioned above.

Examples of the “halogen atom” include a fluorine atom, a chlorine atom, a bromine atom, and an iodine atom.

Examples of the “ring having 3 to 6 carbon atoms” include cyclopropane, cyclobutane, cyclopentane, cyclopentadiene, and cyclohexane.

Examples of the alkylthio group having 1 to 6 carbon atoms” include a methylthio group, an ethylthio group, a propylthio group, a butylthio group, a pentylthio group, and a hexylthio group.

The polymer preferably further contains a disulfide bond in the main chain.

The polymer preferably contains an arylene group having 6 to 40 carbon atoms that may be substituted with a substituent. The meaning of the substituent is the same as the content mentioned above.

Examples of the “arylene group having 6 to 40 carbon atoms” include a phenylene group, an o-methylphenylene group, an m-methylphenylene group, a p-methylphenylene group, an o-chlorophenylene group, an m-chlorophenylene group, a p-chlorophenylene group, an o-fluorophenylene group, a p-fluorophenylene group, an o-methoxyphenylene group, a p-methoxyphenylene group, a p-nitrophenylene group, a p-cyanophenylene group, an α-naphthylene group, a β-naphthylene group, an o-biphenylylene group, an m-biphenylylene group, a p-biphenylylene group, a 1-anthrylene group, a 2-anthrylene group, a 9-anthrylene group, a 1-phenanthrylene group, a 2-phenanthrylene group, a 3-phenanthrylene group, a 4-phenanthrylene group, and a 9-phenanthrylene group.

A weight average molecular weight of the polymer is, for example, within the range of 2,000 to 50,000.

Examples of a monomer that forms the structural unit represented by Formula (3) above, in which m₁ and m₂ represent 1, include compounds having two epoxy groups represented by Formula (10-a) to Formula (10-k) below.

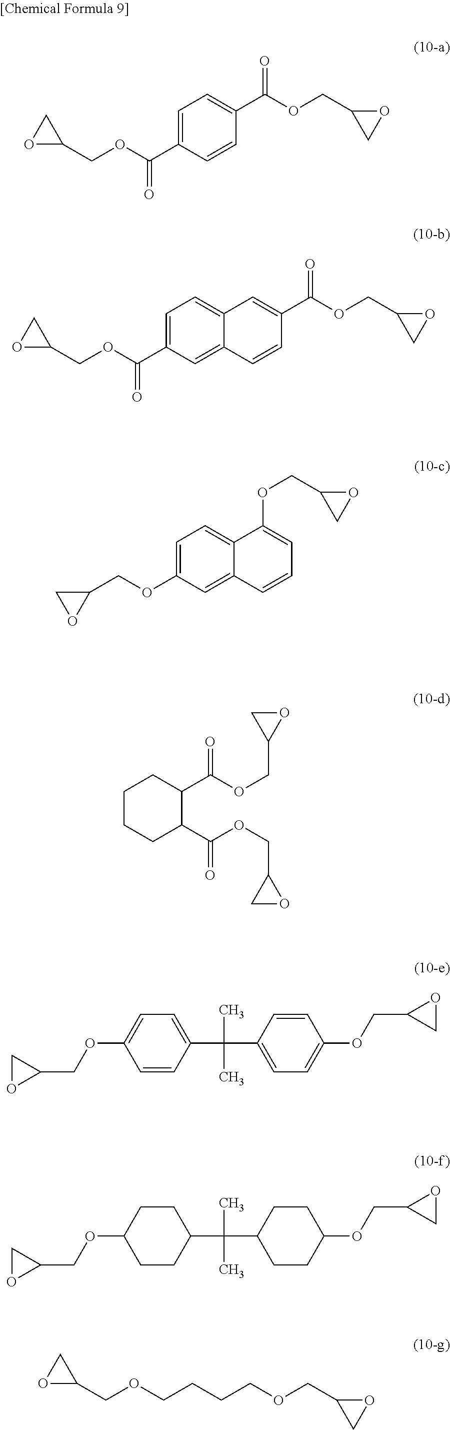

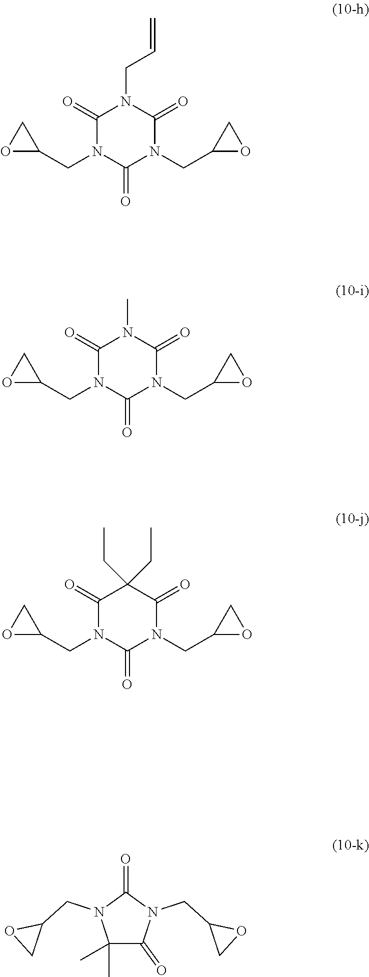

That is, such compounds include 1,4-diglycidyl terephthalate, 2,6-diglycidyl naphthalenedicarboxylate, 1,6-dihydroxynaphthalene diglycidyl, 1,2-diglycidyl cyclohexanedicarboxylate, 2,2-bis(4-hydroxyphenyl)propane diglycidyl, 2,2-bis(4-hydroxycyclohexane)propane diglycidyl, 1,4-butanediol diglycidyl, diglycidyl monoallylisocyanurate, diglycidyl monomethylisocyanurate, 5,5-diglycidyl diethylbarbiturate, and 5,5-dimethylhydantoin diglycidyl, but are not limited thereto.

Examples of a monomer that forms the structural unit represented by Formula (3) above, in which m₁ and m₂ are represented by 0, include compounds having two carboxyl groups, hydroxyphenyl groups, or imide groups represented by Formula (11-a) to Formula (11-s) below, and acid dianhydrides.

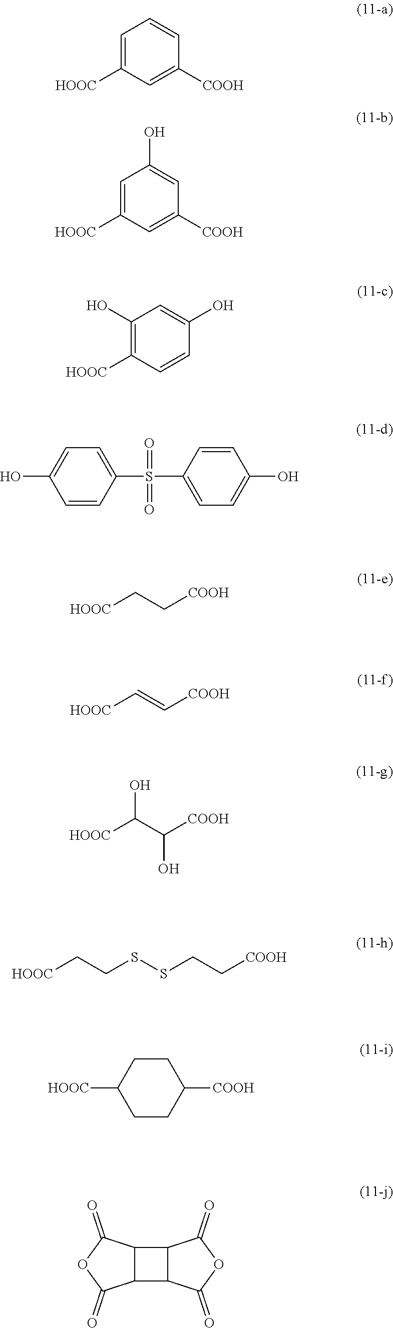

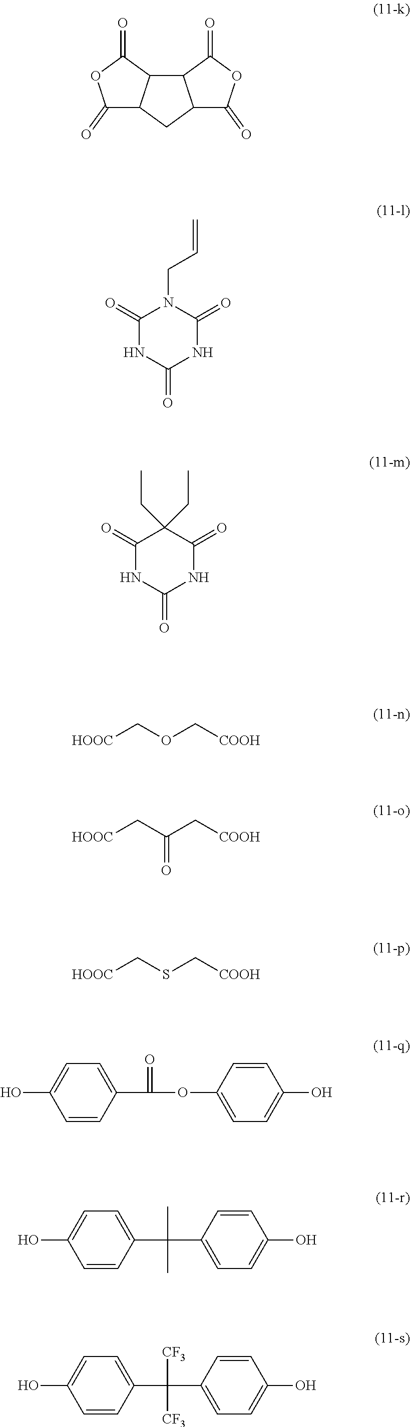

That is, such compounds and acid dianhydrides include isophthalic acid, 5-hydroxyisophthalic acid, 2,4-dihydroxybenzoic acid, 2,2-bis(4-hydroxyphenyl)sulfone, succinic acid, fumaric acid, tartaric acid, 3,3′-dithiodipropionic acid, 1,4-cyclohexanedicarboxylic acid, cyclobutanoic dianhydride, cyclopentanoic dianhydride, monoallylisocyanuric acid, 5,5-diethylbarbituric acid, diglycolic acid, acetonedicarboxylic acid, 2,2′-thiodiglycolic acid, 4-hydroxybenzoic acid-4-hydroxyphenyl, 2,2-bis(4-hydroxyphenyl)propane, 2,2-bis(4-hydroxyphenyl)hexafluoropropane, 1,3-bis(carboxymethyl)-5-methyl isocyanurate, and 1,3-bis(carboxymethyl)-5-allyl isocyanurate, and but are not limited thereto.

The monomer that forms the structural unit represented by Formula (3) above, in which m1 and m2 are represented by 0, may be a compound represented by Formula (11) below.

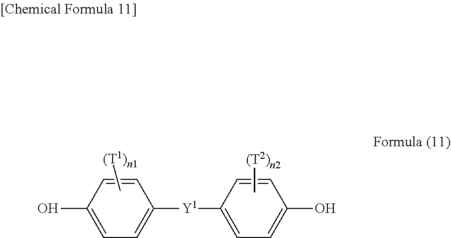

(In Formula (11),
Y¹ represents an alkylene group or a sulfonyl group having 1 to 10 carbon atoms optionally substituted with a single bond, an oxygen atom, a sulfur atom, a halogen atom, or an aryl group having 6 to 40 carbon atoms,
T¹ and T² represent an alkyl group having 1 to 10 carbon atoms, and
n1 and n2 each independently represent an integer of 0 to 4.)

The alkyl group is as mentioned above.

Examples of the aryl group mentioned above include a phenyl group, an o-methylphenyl group, an m-methylphenyl group, a p-methylphenyl group, an o-chlorophenyl group, an m-chlorophenyl group, a p-chlorophenyl group, an o-fluorophenyl group, a p-fluorophenyl group, an o-methoxyphenyl group, a p-methoxyphenyl group, a p-nitrophenyl group, a p-cyanophenyl group, an α-naphthyl group, a β-naphthyl group, an o-biphenyl group, an m-biphenyl group, a p-biphenyl group, a 1-anthryl group, a 2-anthryl group, a 9-anthryl group, a 1-phenanthryl group, a 2-phenanthryl group, a 3-phenanthryl group, a 4-phenanthryl group, and 9-phenanthryl group.

Examples of the alkylene group include a methylene group, an ethylene group, an n-propylene group, an isopropylene group, a cyclopropylene group, an n-butylene group, an isobutylene group, an s-butylene group, a t-butylene group, a cyclobutylene group, a 1-methyl-cyclopropylene group, a 2-methyl-cyclopropylene group, an n-pentylene group, a 1-methyl-n-butylene group, a 2-methyl-n-butylene group, a 3-methyl-n-butylene group, a 1,1-dimethyl-n-propylene group, a 1,2-dimethyl-n-propylene group, a 2,2-dimethyl-n-propylene, a 1-ethyl-n-propylene group, a cyclopentylene group, a 1-methyl-cyclobutylene group, a 2-methyl-cyclobutylene group, a 3-methyl-cyclobutylene group, a 1,2-dimethyl-cyclopropylene group, a 2,3-dimethyl-cyclopropylene group, a 1-ethyl-cyclopropylene group, a 2-ethyl-cyclopropylene group, an n-hexylene group, a 1-methyl-n-pentylene group, a 2-methyl-n-pentylene group, a 3-methyl-n-pentylene group, a 4-methyl-n-pentylene group, a 1,1-dimethyl-n-butylene group, a 1,2-dimethyl-n-butylene group, a 1,3-dimethyl-n-butylene group, a 2,2-dimethyl-n-butylene group, a 2,3-dimethyl-n-butylene group, a 3,3-dimethyl-n-butylene group, a 1-ethyl-n-butylene group, a 2-ethyl-n-butylene group, a 1,1,2-trimethyl-n-propylene group, a 1,2,2-trimethyl-n-propylene group, a 1-ethyl-1-methyl-n-propylene group, a 1-ethyl-2-methyl-n-propylene group, a cyclohexylene group, a 1-methyl-cyclopentylene group, a 2-methyl-cyclopentylene group, a 3-methyl-cyclopentylene group, a 1-ethyl-cyclobutylene group, a 2-ethyl-cyclobutylene group, a 3-ethyl-cyclobutylene group, a 1,2-dimethyl-cyclobutylene group, a 1,3-dimethyl-cyclobutylene group, a 2,2-dimethyl-cyclobutylene group, a 2,3-dimethyl-cyclobutylene group, a 2,4-dimethyl-cyclobutylene group, a 3,3-dimethyl-cyclobutylene group, a 1-n-propyl-cyclopropylene group, a 2-n-propyl-cyclopropylene group, a 1-isopropyl-cyclopropylene group, a 2-isopropyl-cyclopropylene group, a 1,2,2-trimethyl-cyclopropylene group, a 1,2,3-trimethyl-cyclopropylene group, a 2,2,3-trimethyl-cyclopropylene group, a 1-ethyl-2-methyl-cyclopropylene group, a 2-ethyl-1-methyl-cyclopropylene group, a 2-ethyl-2-methyl-cyclopropylene group, a 2-ethyl-3-methyl-cyclopropylene group, an n-heptylene group, an n-octylene group, an n-nonylene group, and an n-decanylene group.

Y¹ is preferably a sulfonyl group.

A copolymerization ratio (feed weight ratio) of the monomer (bifunctional) that forms the structural unit represented by Formula (3) above, in which m₁ and m₂ represent 1, vs. the monomer (bifunctional) that forms the structural unit represented by Formula (3) above, in which m₁ and m₂ are represented by 0, is, for example, within the range of from 1:2 to 2:1.

In addition, a feed weight ratio of a monomer (a portion that mainly reacts with the polymer is monofunctional) for inducing the acyclic aliphatic hydrocarbon group to be bonded to the terminal of the polymer of the present application, relative to a total amount of the above-mentioned monomers is, for example, 20:1 to 5:1.

The term “functional” is a concept focusing on chemical attributes or chemical reactivity of a substance, and when a functional group is referred to, the inherent physical properties or chemical reactivity of each group is assumed, but in the present application, functional group means a reactive substituent that can be bonded to other compounds.

The number of repetition of the structural unit represented by Formula (3) above is, for example, within the range not less than 5 and not more than 10,000.

Examples of the organic solvent contained in the resist underlayer film-forming composition of the present invention include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2-pentanol, 2-methyl hydroxyisobutyrate, 2-ethyl hydroxyisobutyrate, ethyl ethoxyacetate, 2-hydroxyethyl acetate, 3-methyl methoxypropionate, 3-ethyl methoxypropionate, 3-ethyl ethoxypropionate, 3-methyl ethoxypropionate, methyl pyruvate, ethyl pyruvate, ethyl acetate, butyl acetate, ethyl lactate, butyl lactate, 2-heptanone, methoxycyclopentane, anisole, γ-butyrolactone, N-methylpyrrolidone, N,N-dimethylformamide, and N,N-dimethylacetamide. Such solvents may be used each alone or in combination of two or more.

Of such solvents, propylene glycol monomethyl ether, propylene glycol monomethyl ether acetate, ethyl lactate, butyl lactate, cyclohexanone, and the like are preferable. In particular, propylene glycol monomethyl ether and propylene glycol monomethyl ether acetate are preferable.

Then, the ratio of the organic solvent to the resist underlayer film-forming composition of the present invention is, for example, not less than 50% by mass and not more than 99.9% by mass.

The polymer contained in the resist underlayer film-forming composition of the present invention is, for example, within the range of 0.1% by mass to 50% by mass relative to the resist underlayer film-forming composition.

The resist underlayer film-forming composition of the present invention may include a crosslinking agent and a crosslinking catalyst (curing catalyst) that is a compound for promoting a crosslinking reaction, in addition to the polymer and the organic solvent. When the components excluding the organic solvent in the resist underlayer film-forming composition of the present invention are defined as a solid content, the solid content includes the polymer and additives such as a crosslinking agent and a crosslinking catalyst that are added as necessary. The ratio of the additives is, for example, within the range of 0.1% by mass to 50% by mass, and preferably 1% by mass to 30% by mass, to the solid content of the resist underlayer film-forming composition of the present invention.

Examples of the crosslinking agent that is incorporated as an optional component into the resist underlayer film-forming composition of the present invention include hexamethoxymethylmelamine, tetramethoxymethylbenzoguanamine, 1,3,4,6-tetrakis(methoxymethyl)glycoluril(tetramethoxymethylglycoluril) (POWDERLINK [Registered Trademark] 1174), 1,3,4,6-tetrakis(butoxymethyl)glycoluril, 1,3,4,6-tetrakis(hydroxymethyl)glycoluril, 1,3-bis(hydroxymethyl)urea, 1,1,3,3-tetrakis(butoxymethyl)urea, 1,1,3,3-tetrakis(methoxymethyl)urea, and 3,3′,5,5′-tetrakis(methoxymethyl)4,4′-biphenol.

The crosslinking agent of the present application may be a nitrogen-containing compound that is described in WO 2017/187969 A and has per molecule 2 to 6 substituents represented by Formula (1d) below that is bonded to a nitrogen atom.

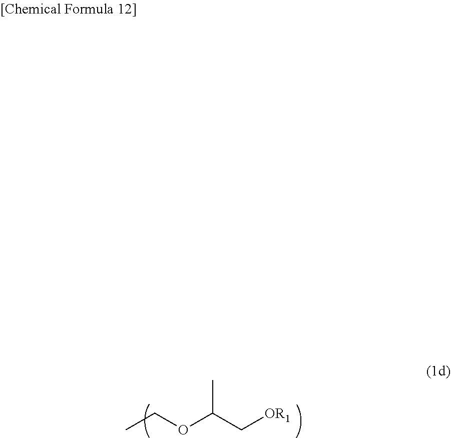

(In Formula (1d), R₁ represents a methyl group or an ethyl group.)

The nitrogen-containing compound having per molecule 2 to 6 substituents represented by Formula (1d) above may be a glycoluril derivative represented by Formula (1E) below.

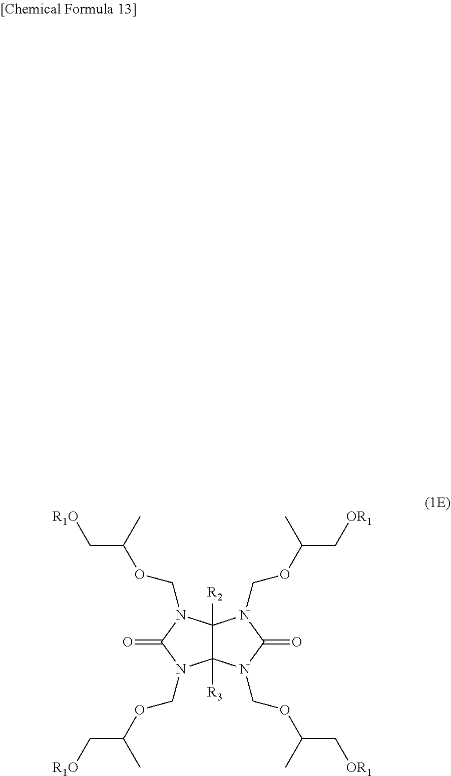

(In Formula (1E), four R₁ each independently represent a methyl group or an ethyl group, and R₂ and R₃ each independently represent a hydrogen atom, an alkyl group having 1 to 4 carbon atoms, or a phenyl group.)

Examples of the glycoluril derivative represented by Formula (1E) include compounds represented by Formula (1E-1) to Formula (1E-6) below.

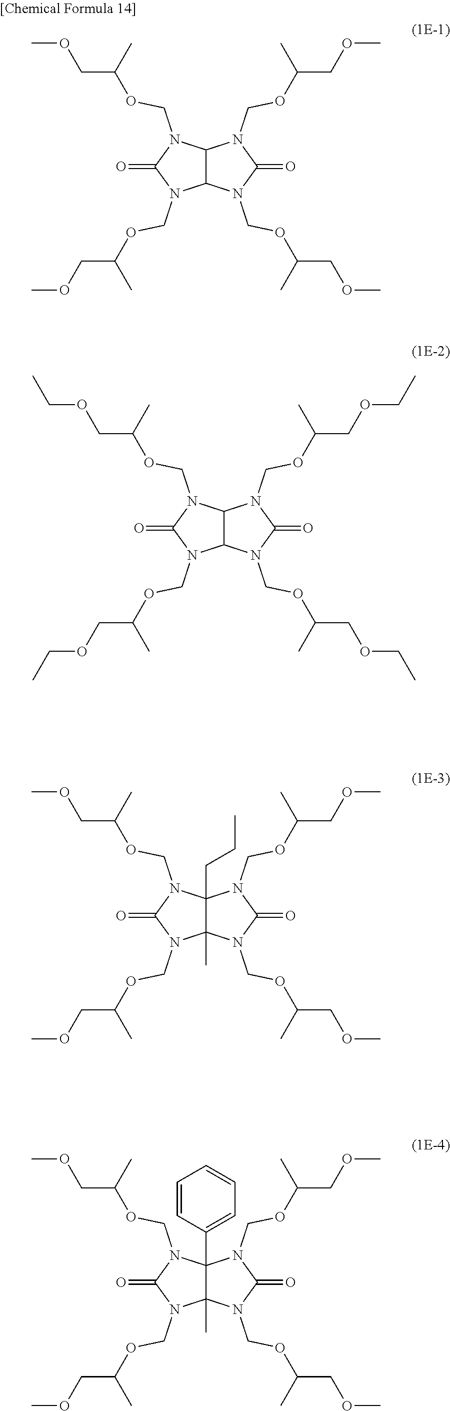

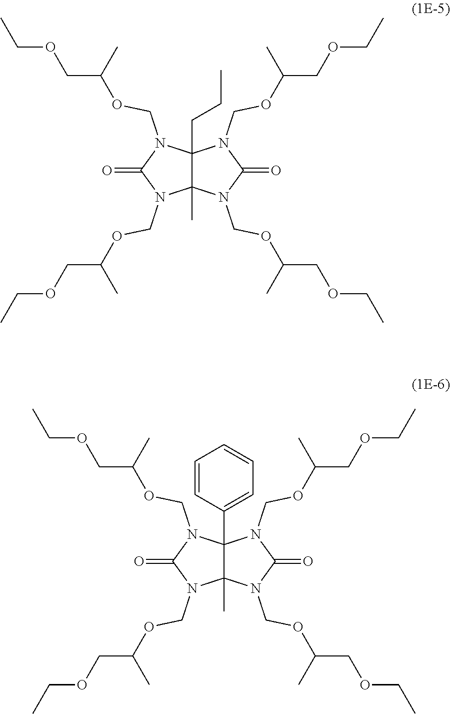

The nitrogen-containing compound having per molecule 2 to 6 substituents represented by Formula (1d) above is obtained by allowing a nitrogen-containing compound represented by Formula (2d) below and having per molecule 2 to 6 substituents bonded to a nitrogen atom to react with at least one compound represented by Formula (3d) below.

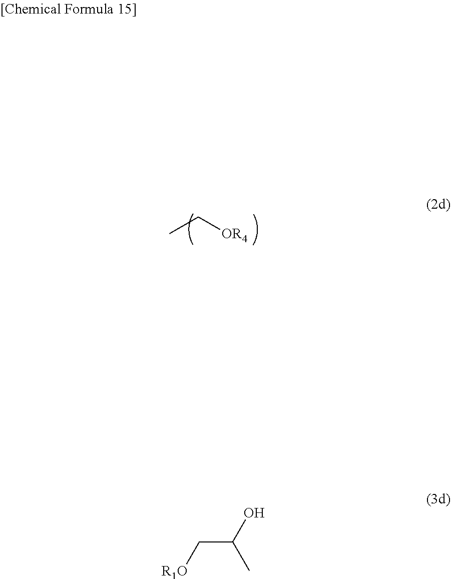

(In Formula (3d), R₁ represents a methyl group or an ethyl group; and in Formula (2d), R₄ represents an alkyl group having 1 to 4 carbon atoms.)

The glycoluril derivative represented by Formula (1E) above is obtained by allowing a glycoluril derivative represented by Formula (2E) below to react with at least one compound represented by Formula (3d) above.

An example of the nitrogen-containing compound having per molecule 2 to 6 substituents represented by Formula (2d) above is a glycoluril derivative represented by Formula (2E) below.

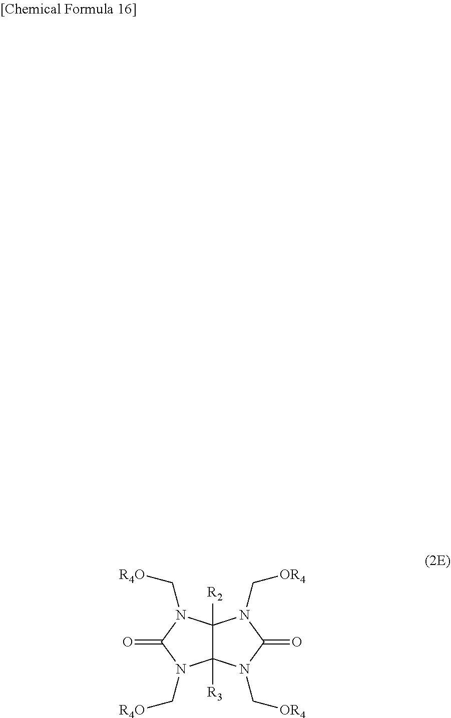

(In Formula (2E), R₂ and R₃ each independently represent a hydrogen atom, an alkyl group having 1 to 4 carbon atoms, or a phenyl group; and each R₄ independently represents an alkyl group having 1 to 4 carbon atoms.)

Examples of the glycoluril derivative represented by Formula (2E) above include compounds represented by Formula (2E-1) to Formula (2E-4) below. Examples of the compound represented by Formula (3d) above include compounds represented by Formula (3d-1) and Formula (3d-2) below.

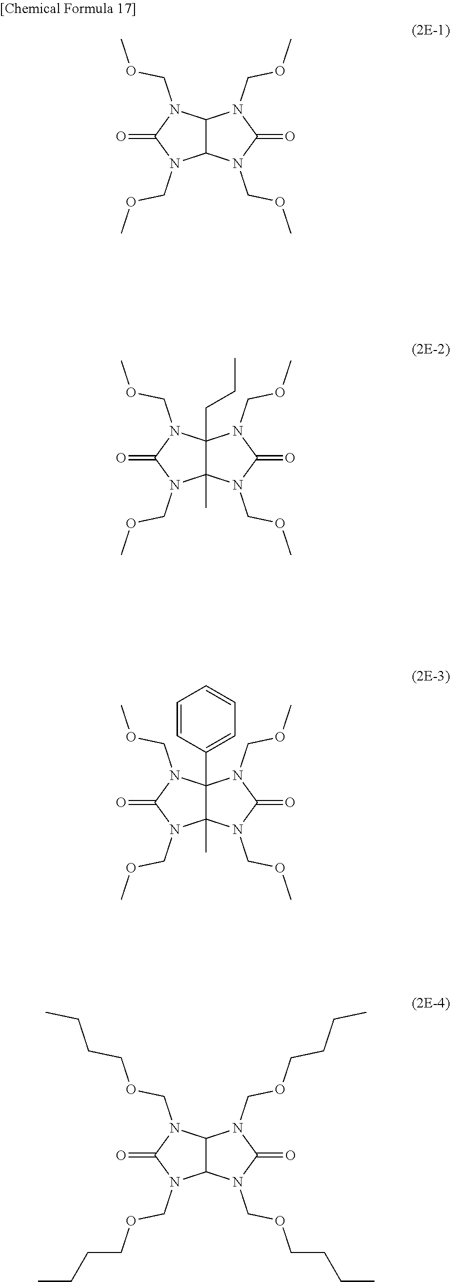

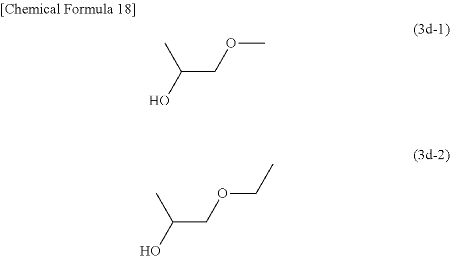

Regarding the details of the above-mentioned nitrogen-containing compound having per molecule 2 to 6 substituents to be bonded to the nitrogen atom and represented by Formula (1d) below, the entire disclosure of WO 2017/187969 A is incorporated herein by reference.

The above-mentioned crosslinking agent may be a crosslinking compound described in WO 2014/208542 A and represented by Formula (G-1) or Formula (G-2) below.

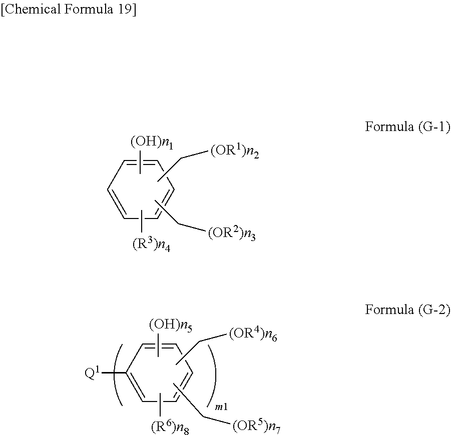

(In the formulas, Q¹ represents a single bond or an m1-valent organic group; R¹ and R⁴ each represent an alkyl group having 2 to 10 carbon atoms or an alkyl group having 2 to 10 carbon atoms having an alkoxy group having 1 to 10 carbon atoms; R² and R⁵ each represent a hydrogen atom or a methyl group; and R³ and R⁶ each represent an alkyl group having 1 to 10 carbon atoms or an aryl group having 6 to 40 carbon atoms.
n1 represents an integer that meets 1≤n1≤3, n2 represents an integer that meets 2≤n2≤5, n3 represents an integer that meets 0≤n3≤3, n4 represents an integer that meets 0≤n4≤3, and (n1+n2+n3+n4) is an integer that meets 3≤(n1+n2+n3+n4)≤6.
n5 represents an integer that meets 1≤n5≤3, n6 represents an integer that meets 1≤n6≤4, n7 represents an integer that meets 0≤n7≤3, n8 represents an integer that meets 0≤n8≤3, and (n5+n6+n7+n8) is an integer that meets 2≤(n5+n6+n7+n8)≤5.
m1 represents an integer of 2 to 10.)

The crosslinking compound represented by Formula (G-1) or Formula (G-2) above may be obtained by allowing a compound represented by Formula (G-3) or Formula (G-4) below to react with a hydroxyl group-containing ether compound or alcohol having 2 to 10 carbon atoms.

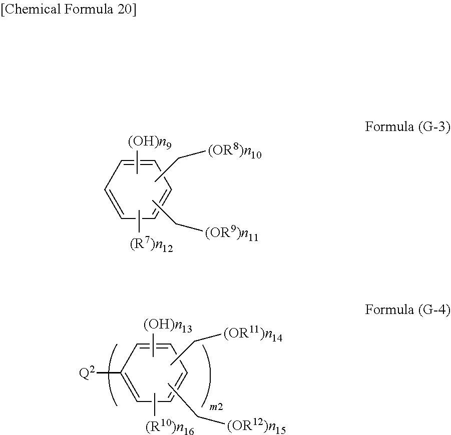

(In the formula, Q² represents a single bond or a m2-valent organic group. R⁸, R⁹, R¹¹, and R¹² each represent a hydrogen atom or a methyl group, and R⁷ and R¹⁰ each represent an alkyl group having 1 to 10 carbon atoms or an aryl group having 6 to 40 carbon atoms.
n9 represents an integer that meets 1≤n9≤3, n10 represents an integer that meets 2≤n10≤5, n11 represents an integer that meets 0≤n11≤3, n12 represents an integer that meets 0≤n12≤3, and (n9+n10+n11+n12) is an integer that meets 3<(n9+n0+n11+n12)≤6.
n13 represents an integer that meets 1≤n13≤3, n14 represents an integer that meets 1≤n14≤4, n15 represents an integer that meets 0≤n15≤3, n16 represents an integer that meets 0≤n16≤3, and (n13+n14+n15+n16) is an integer that meets 2<(n13+n14+n15+n16)≤5.
m2 represents an integer of 2 to 10.)

Examples of the compounds represented by Formula (G-1) and Formula (G-2) above include compounds below.

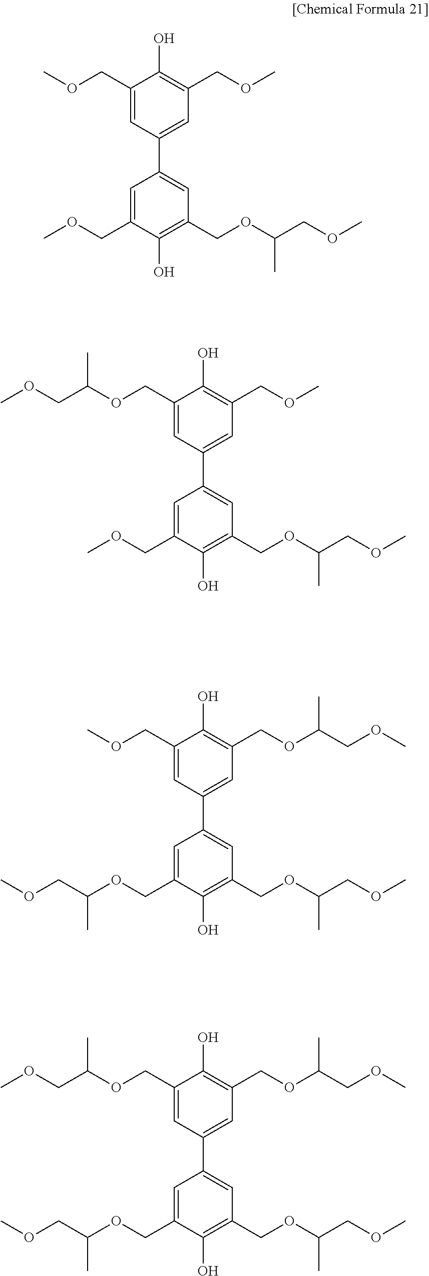

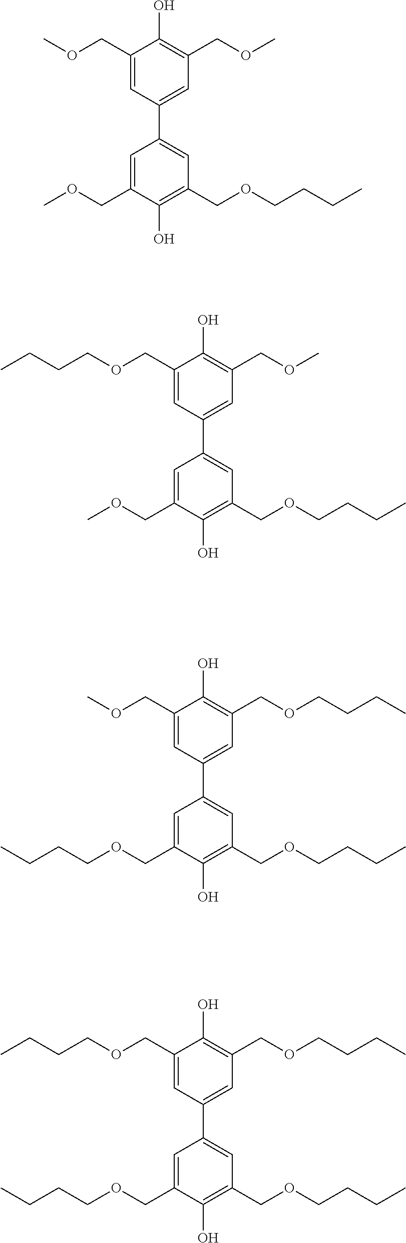

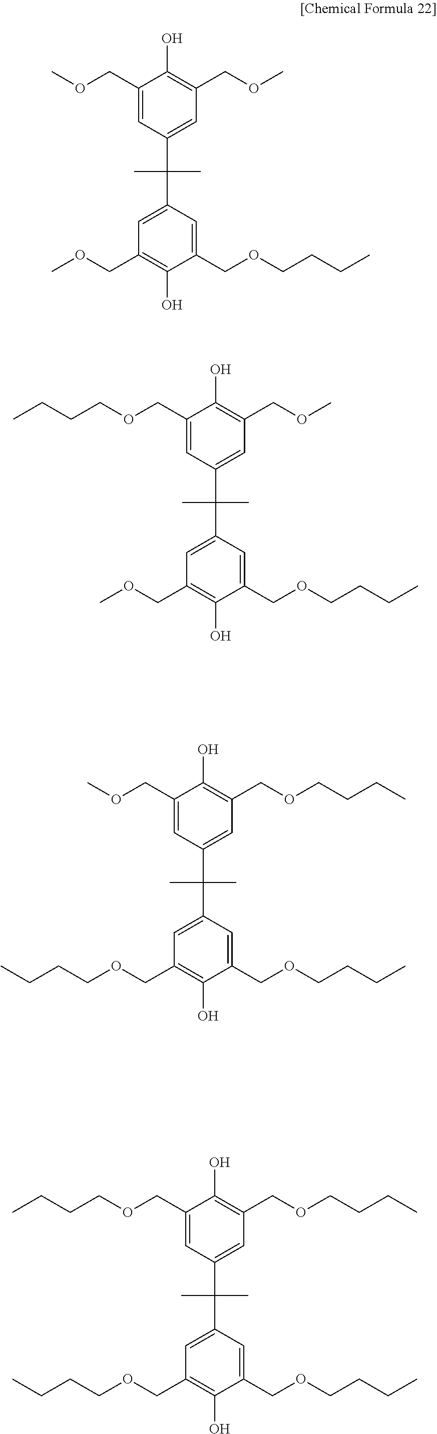

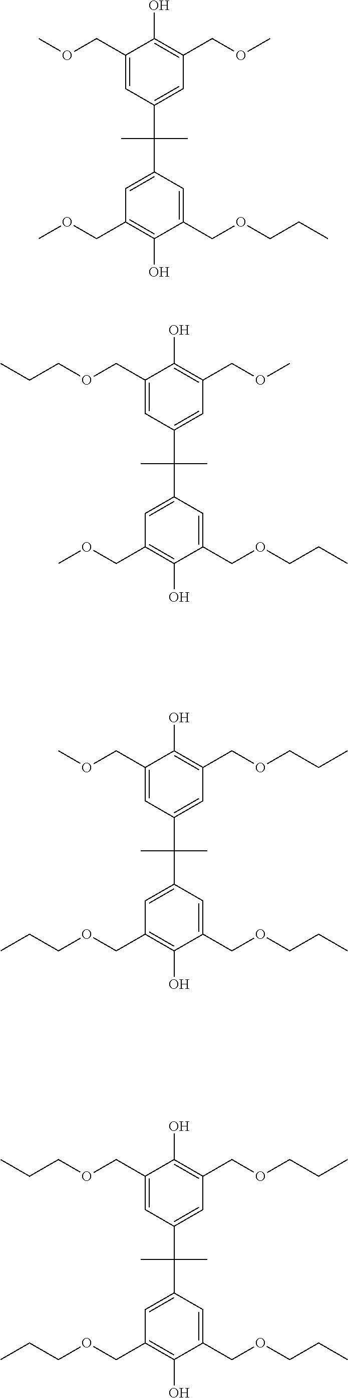

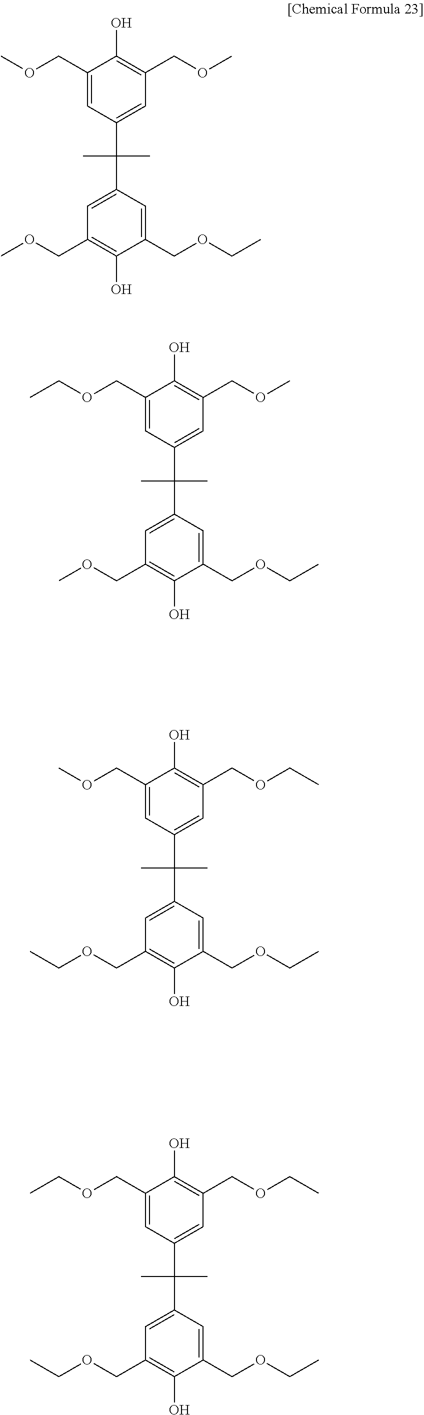

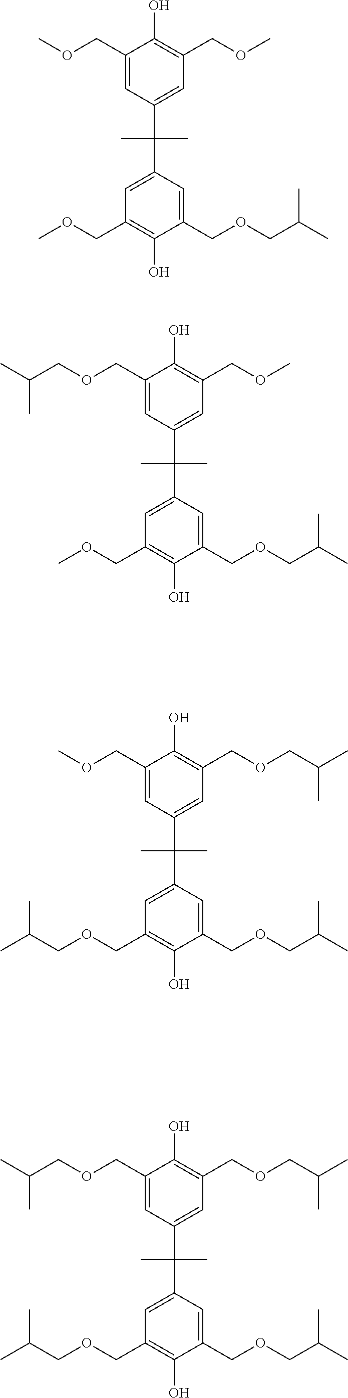

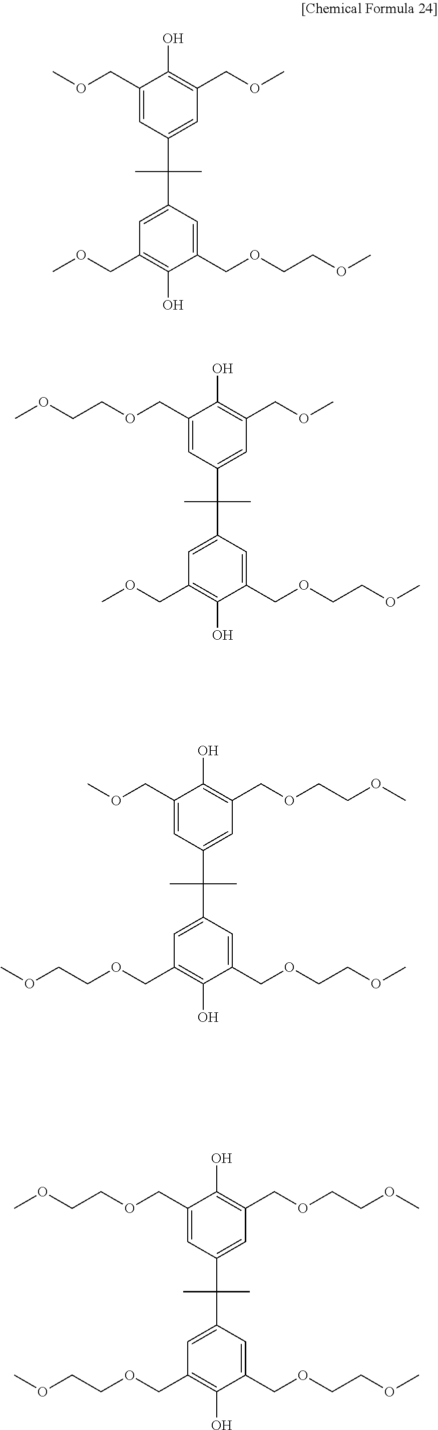

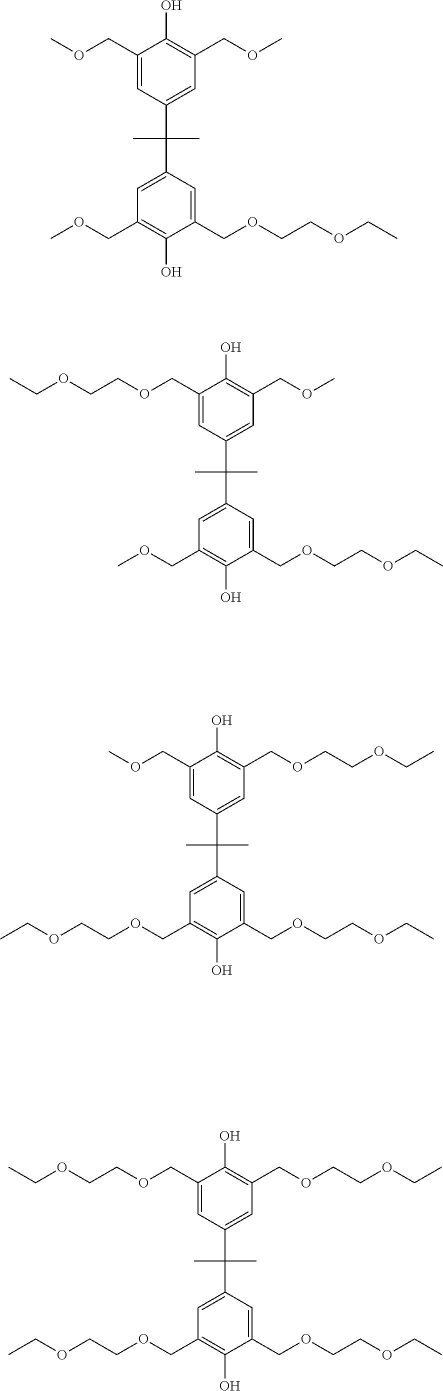

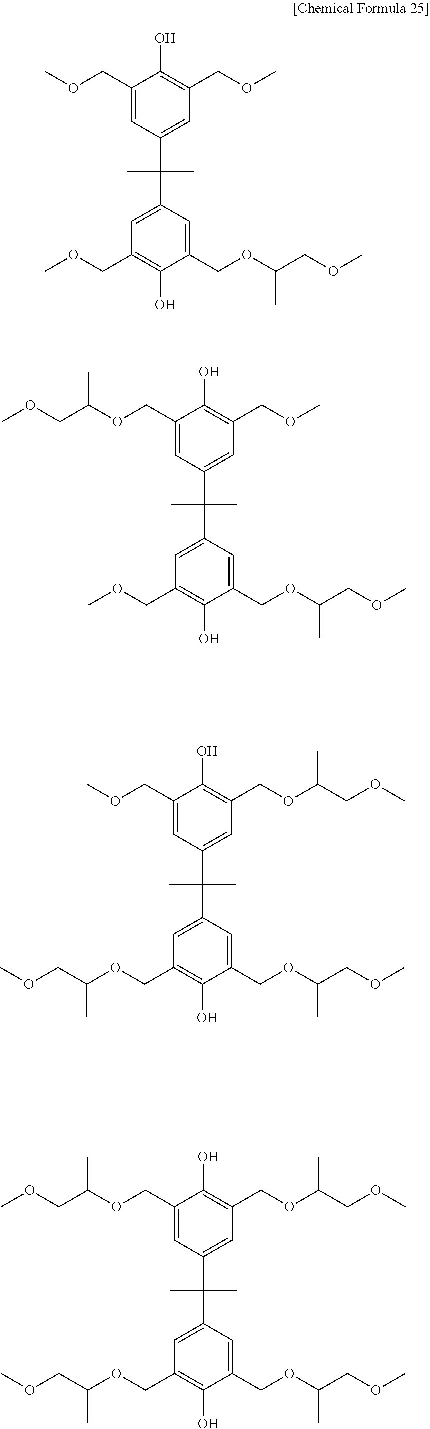

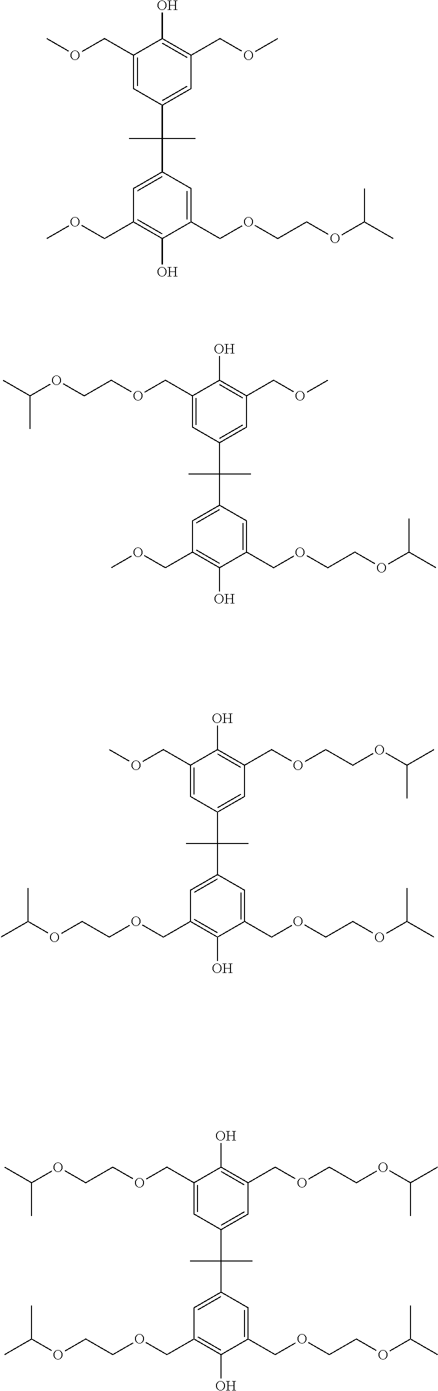

Examples of the compounds represented by Formula (G-3) and Formula (G-4) include compounds below.

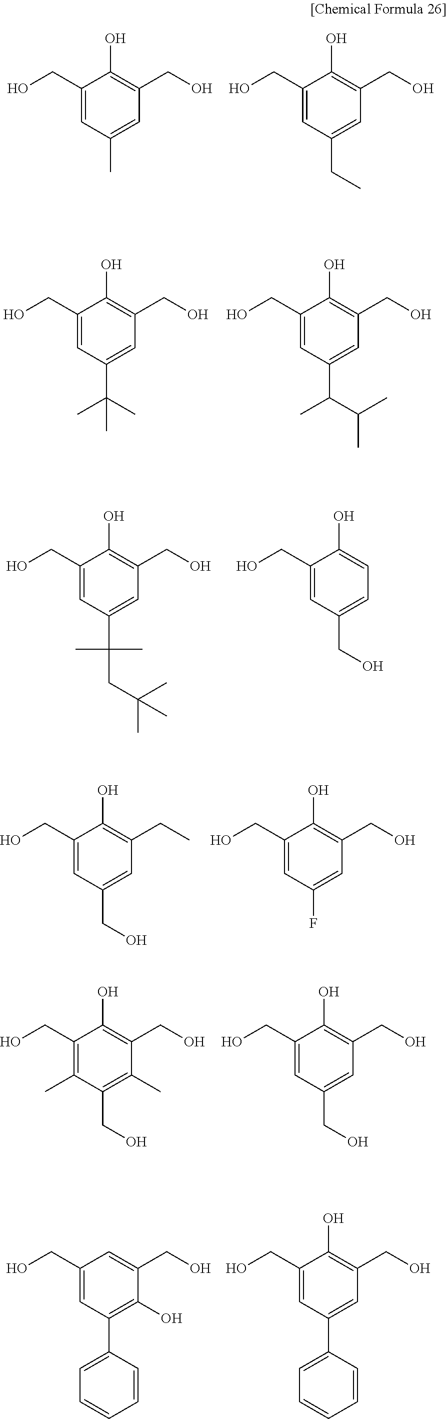

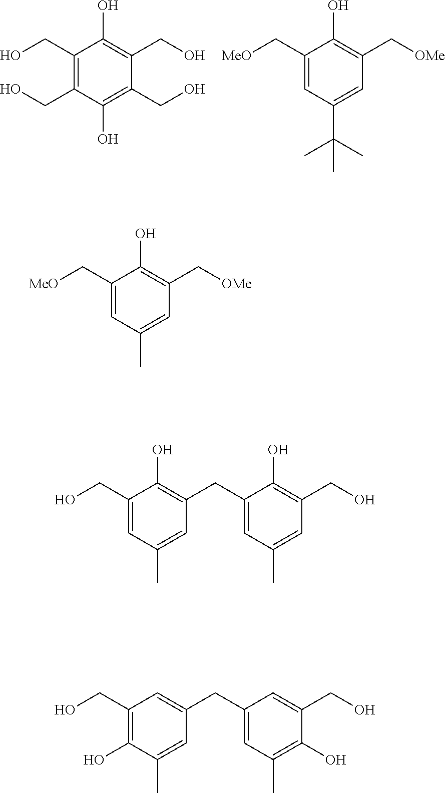

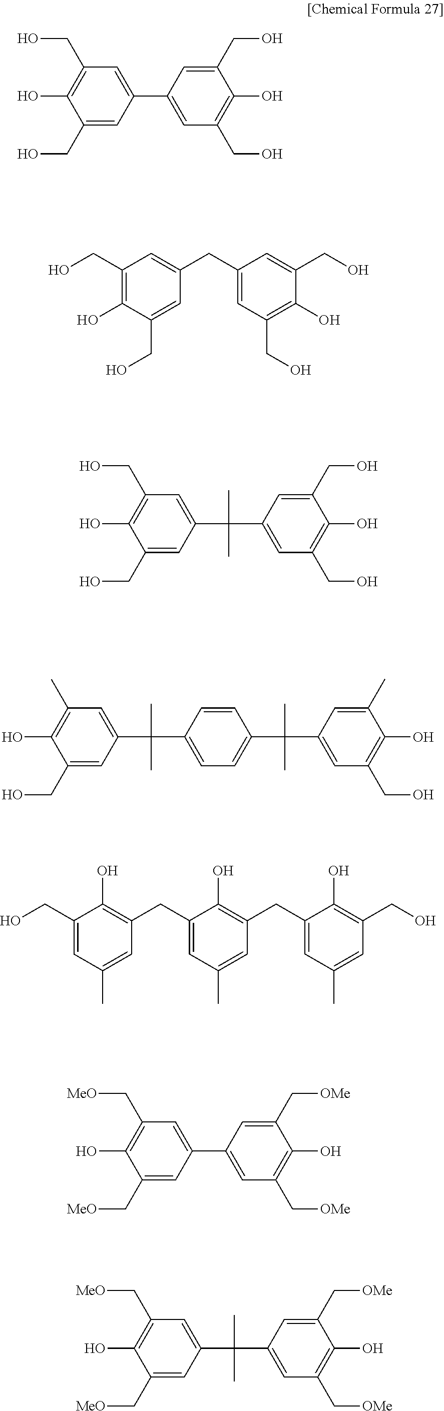

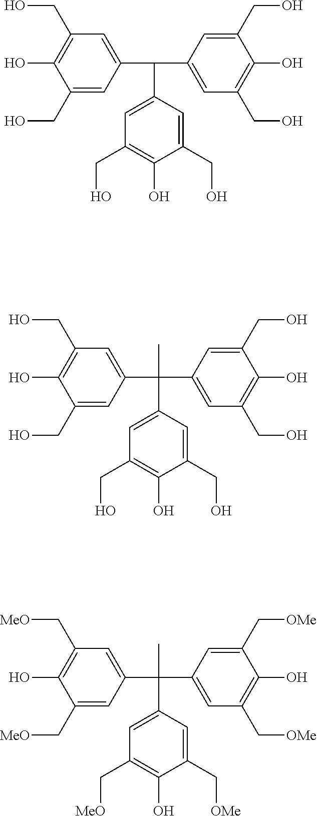

In the formulas, Me represents a methyl group.

The entire disclosure of WO 2014/208542 A is incorporated herein by reference.

When the above-mentioned crosslinking agent is used, the content of the crosslinking agent is, for example, within the range of 1% by mass to 50% by mass, and preferably 5% by mass to 30% by mass, relative to the above-mentioned polymer.

Examples of the curing catalyst (crosslinking catalyst) that is incorporated as an optional component into the resist underlayer film-forming composition of the present invention include sulfonic acid compounds and carboxylic acid compounds such as p-toluenesulfonic acid, trifluoromethane sulfonic acid, pyridinium-p-toluene sulfonate (pyridinium-p-toluenesulfonic acid), pyridinium-p-hydroxybenzene sulfonic acid, pyridinium-trifluoromethane sulfonic acid, cyclohexyl p-toluene sulfonate, morpholine, p-toluene sulfonate, salicylic acid, camphor sulfonic acid, 5-sulfosalicylic acid, 4-chlorobenzene sulfonic acid, 4-hydroxybenzene sulfonic acid, benzene disulfonic acid, 1-naphthalene sulfonic acid, citric acid, benzoic acid, and hydroxybenzoic acid. When the above-mentioned crosslinking catalyst is used, the content of the crosslinking catalyst is, for example, within the range of 0.1% by mass to 50% by mass, and preferably 1% by mass to 30% by mass, relative to the above-mentioned crosslinking agent.

To eliminate the occurrence of pinholes, striation, or the like, and to further improve applicability to surface unevenness, a surfactant may be further added to the resist underlayer film-forming composition of the present invention. Examples of the surfactant include nonionic surfactants such as polyoxyethylene alkyl ethers including polyoxyethylene lauryl ether, polyoxyethylene stearyl ether, polyoxyethylene cetyl ether, and polyoxyethylene oleyl ether, polyoxyethylene alkyl aryl ethers including polyoxyethylene octyl phenol ether and polyoxyethylene nonyl phenol ether, polyoxyethylene/polyoxypropylene block copolymers, sorbitan fatty acid esters including sorbitan monolaurate, sorbitan monopalmitate, sorbitan monostearate, sorbitan monooleate, sorbitan trioleate, and sorbitan tristearate, and polyoxyethylenesorbitan fatty acid esters including polyoxyethylenesorbitan monolaurate, polyoxyethylenesorbitan monopalmitate, polyoxyethylenesorbitan monostearate, polyoxyethylenesorbitan trioleate, and polyoxyethylenesorbitan tristearate, fluorosurfactants including EFTOP series EF301, EF303, and EF352 (product names, manufactured by Tohkem Products Corporation), MEGAFACE series F171, F173, and R-30 (product names, manufactured by Dainippon Ink and Chemicals, Incorporated), Fluorad series FC430 and FC431 (product names, manufactured by Sumitomo 3M Ltd.), AsahiGuard AG710 and Surflon series S-382, SC101, SC102, SC103, SC104, SC105, and SC106 (product names, manufactured by Asahi Glass Co., Ltd.), and organosiloxane polymer KP341 (manufactured by Shin-Etsu Chemical Co., Ltd.). The blending amount of the surfactant is usually not more than 2.0% by mass, and preferably not more than 1.0% by mass, relative to the total solid content of the resist underlayer film-forming composition of the present invention. The surfactants may be added each alone or in combination of two or more.

### <Resist Underlayer Film>

A resist underlayer film according to the present invention may be manufactured by applying the above-mentioned resist underlayer film-forming composition on a semiconductor substrate and baking the resist underlayer film-forming composition.

Examples of the semiconductor substrate on which the resist underlayer film-forming composition of the present invention is applied include a silicon wafer, a germanium wafer, and a compound semiconductor wafer such as gallium arsenide, indium phosphide, gallium nitride, indium nitride, or aluminum nitride.

When a semiconductor substrate having an inorganic film formed on a surface is used, the inorganic film is formed by, for example, an atomic layer deposition (ALD) method, a chemical vapor deposition (CVD) method, a reactive sputtering method, an ion plating method, a vacuum deposition method, or a spin coating method (spin on glass: SOG). Examples of the inorganic film include a polysilicon film, a silicon oxide film, a silicon nitride film, a boro-phospho silicate glass (BPSG) film, a titanium nitride film, a titanium oxynitride film, a tungsten film, a gallium nitride film, and a gallium arsenide film.

The resist underlayer film-forming composition of the present invention is applied on such a semiconductor substrate by an appropriate application method such as a spinner or a coater. Thereafter, the resist underlayer film-forming composition is baked with a heating device such as a hot plate to form a resist underlayer film. Baking conditions are appropriately selected from baking temperatures of 100° C. to 400° C. and baking times of 0.3 minutes to 60 minutes. Preferably, the baking temperature is 120° C. to 350° C. and the baking time is 0.5 minutes to 30 minutes, and more preferably, the baking temperature is 150° C. to 300° C. and the baking time is 0.8 minutes to 10 minutes.

A film thickness of the resist underlayer film to be formed is, for example, 0.001 μm (1 nm) to 10 μm, 0.002 μm (2 nm) to 1 μm, 0.005 μm (5 nm) to 0.5 μm (500 nm), 0.001 μm (1 nm) to 0.05 μm (50 nm), 0.002 μm (2 nm) to 0.05 μm (50 nm), 0.003 μm (3 nm) to 0.05 μm (50 nm), 0.004 μm (4 nm) to 0.05 μm (50 nm), 0.005 μm (5 nm) to 0.05 μm (50 nm), 0.003 μm (3 nm) to 0.03 μm (30 nm), 0.003 μm (3 nm) to 0.02 μm (20 nm), 0.005 μm (5 nm) to 0.02 μm (20 nm), 0.003 μm (3 nm) 0.01 μm (10 nm), 0.005 μm (5 nm) to 0.01 μm (10 nm), 0.003 μm (3 nm) to 0.006 μm (6 nm), and 0.005 μm (5 nm). When the temperature during baking is lower than the above-mentioned range, crosslinking may be insufficient. On the other hand, when the temperature during baking is higher than the above-mentioned range, the resist underlayer film may be decomposed by heat.

### <Method for Manufacturing Patterned Substrate and Method for Manufacturing Semiconductor Device>

A method for manufacturing a patterned substrate includes the following steps. Usually, the patterned substrate is manufactured by forming a photoresist layer on the resist underlayer film. The photoresist that is formed on the resist underlayer film by application and baking according to a known method is not particularly limited as long as the resist is sensitive to light to be used for exposure. Any of negative photoresist and positive photoresist may be used. There are a positive photoresist made of novolak resin and 1,2-naphthoquinonediazide sulfonic acid ester; chemically amplified photoresists made of a binder having a group that is decomposed by an acid to increase an alkali dissolution rate, and a photoacid generator; chemically amplified photoresists made of a low molecular weight compound that is decomposed by an acid to increase the alkali dissolution rate of the photoresist, an alkali-soluble binder, and a photoacid generator; chemically amplified photoresists made of a binder having a group that is decomposed by an acid to increase the alkali dissolution rate, a low molecular weight compound that is decomposed by an acid to increase the alkali dissolution rate of the photoresist, and a photoacid generator; resists containing metal elements, and the like. Examples include V146G, product name, manufactured by JSR Corporation, APEX-E, product name, manufactured by Shipley Company, L.L.C., PAR710, product name, manufactured by Sumitomo Chemical Company, Limited, and AR2772 and SEPR430, product names, manufactured by Shin-Etsu Chemical Co., Ltd. Examples further include fluorine atom-containing polymer-based photoresists such as those described in Proc. SPIE, Vol. 3999, 330-334 (2000), Proc. SPIE, Vol. 3999, 357-364 (2000), or Proc. SPIE, Vol. 3999, 365-374 (2000).

Examples further include fluorine atom-containing polymer-based photoresists such as those described in Proc. SPIE, Vol. 3999, 330-334 (2000), Proc. SPIE, Vol. 3999, 357-364 (2000), or Proc. SPIE, Vol. 3999, 365-374 (2000). The so-called metal-containing resists (metal resists) that contain metal may be used. As a specific example, the so-called resist compositions and metal-containing resist compositions such as resist compositions, radiation-sensitive resin compositions, high-resolution patterning compositions based on an organic metal solutions described in WO 2019/188595 A, WO 2019/187881 A, WO 2019/187803 A, WO 2019/167737 A, WO 2019/167725 A, WO 2019/187445 A, WO 2019/167419 A, WO 2019/123842 A, WO 2019/054282 A, WO 2019/058945 A, WO 2019/058890 A, WO 2019/039290 A, WO 2019/044259 A, WO 2019/044231 A, WO 2019/026549 A, WO 2018/193954 A, WO 2019/172054 A, WO 2019/021975 A, WO 2018/230334 A, WO 2018/194123 A, JP 2018-180525 A, WO 2018/190088 A, JP 2018-070596 A, JP 2018-028090 A, JP 2016-153409 A, JP 2016-130240 A, JP 2016-108325 A, JP 2016-047920 A, JP 2016-035570 A, JP 2016-035567 A, JP 2016-035565 A, JP 2019-101417 A, JP 2019-117373 A, JP 2019-052294 A, JP 2019-008280 A, JP 2019-008279 A, JP 2019-003176 A, JP 2019-003175 A, JP 2018-197853 A, JP 2019-191298 A, JP 2019-061217 A, JP 2018-045152 A, JP 2018-022039 A, JP 2016-090441 A, JP 2015-10878 A, JP 2012-168279 A, JP 2012-022261 A, JP 2012-022258 A, JP 2011-043749 A, JP 2010-181857 A, JP 2010-128369 A, WO 2018/031896 A, JP 2019-113855 A, WO 2017/156388 A, WO 2017/066319 A, JP 2018-41099 A, WO 2016/065120 A, WO 2015/026482 A, JP 2016-29498 A, and JP 2011-253185 A may be used, but the present invention are not limited thereto.

Examples of the resist composition include the following.

Active ray-sensitive or radiation-sensitive resin composition that includes resin A, and a compound represented by General Formula (1), the resin A having a repeating unit having an acid-decomposable group, in which a polar group is protected by a protective group that leaves by an action of an acid.

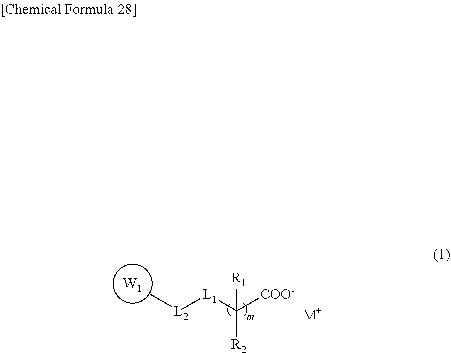

In General Formula (1), m represents an integer of 1 to 6.
R₁ and R₂ each independently represent a fluorine atom or a perfluoroalkyl group.
L₁ represents —O—, —S—, —COO—, —SO₂—, or —SO₃—.
L₂ represents a single bond or an alkylene group that optionally has a substituent.
W₁ represents a cyclic organic group that optionally has a substituent.
M⁺ represents a cation.

A metal-containing film-forming composition for extreme ultraviolet or electron beam lithography that contains a compound having a metal-oxygen covalent bond, and a solvent, in which the metal element that composes the compound belongs to Period 3 to Period 7 of Group 3 to Group 15 of the periodic table.

A radiation-sensitive resin composition containing a polymer and an acid generator, the polymer having a first structural unit represented by Formula (1) below and a second structural unit represented by Formula (2) below containing an acid-dissociating group.

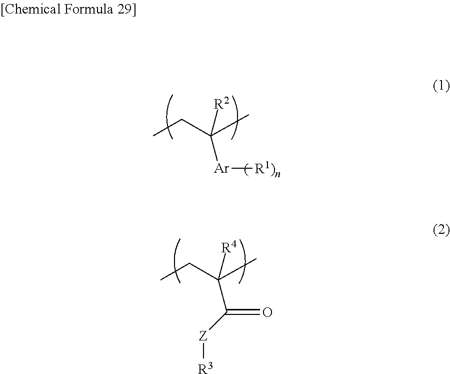

(In Formula (1), Ar is a group resulting from eliminating (n+1) hydrogen atoms from an arene having a carbon number of 6 to 20. R¹ is a hydroxy group, a sulfanyl group, or a monovalent organic group having a carbon number of 1 to 20. n is an integer of 0 to 11. When n is not less than 2, a plurality of R¹ are the same or different. R² is a hydrogen atom, a fluorine atom, a methyl group, or a trifluoromethyl group.

In Formula (2), R³ is a monovalent group having a carbon number of 1 to 20 and containing the acid-dissociating group. Z is a single bond, an oxygen atom, or a sulfur atom. R⁴ is a hydrogen atom, a fluorine atom, a methyl group, or a trifluoromethyl group.)

A resist composition that contains resin (A1) and an acid generator, the resin containing a structural unit having a cyclic carbonate ester structure, a structural unit represented by Formula (II), and a structural unit having an acid-labile group.

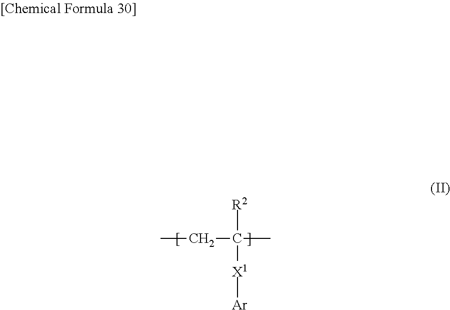

[In Formula (II),
R² represents a hydrogen atom, a halogen atom, or an alkyl group with a carbon number of 1 to 6 that optionally has a halogen atom; X¹ represents a single bond, —CO—O—*, or —CO—NR⁴—*, * represents a bond to —Ar; R⁴ represents a hydrogen atom or an alkyl group with a carbon number of 1 to 4; and Ar represents an aromatic hydrocarbon group with a carbon number of 6 to 20 that optionally has one or more groups selected from the group consisting of a hydroxy group and a carboxyl group.]

A resist composition that generates an acid upon exposure and changes in solubility with respect to a developer by the action of the acid,
which contains a substrate component (A) that changes in solubility with respect to a developer by the action of the acid, and a fluorine additive component (F) that exhibits decomposability with respect to an alkali developer,
wherein the fluorine additive component (F) contains a fluororesin component (F1) having a constituent unit (f1) containing a base-dissociable group and a constituent unit (f2) represented by General Formula (f2-r-1) below.

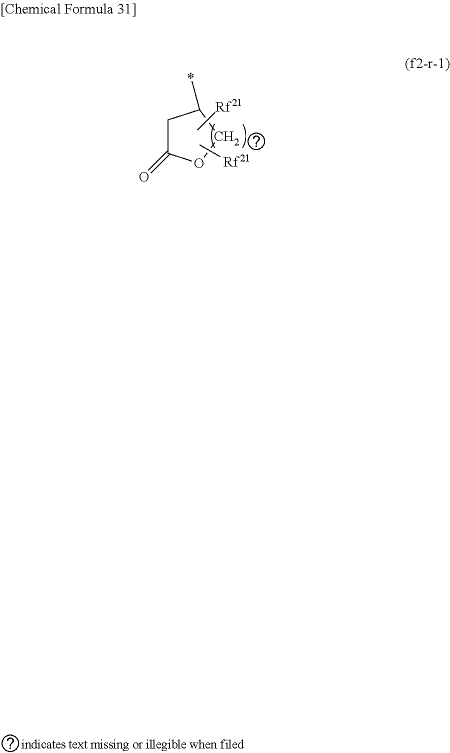

[In Formula (f2-r-1), each Rf²¹ independently represents a hydrogen atom, an alkyl group, an alkoxy group, a hydroxyl group, a hydroxyalkyl group, or a cyano group. n″ is an integer of 0 to 2. * is a bond.]

The resist composition, in which the constituent unit (f1) contains a constituent unit represented by General Formula (f1-1) below or a constituent unit represented by General Formula (f1-2) below.

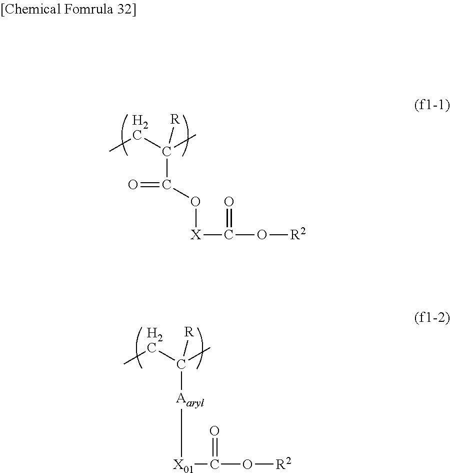

[In Formula (f1-1) and Formula (f1-2), each R independently represents a hydrogen atom, an alkyl group with a carbon number of 1 to 5, or a halogenated alkyl group with a carbon number of 1 to 5. X is a divalent linking group having no acid-dissociating portion. A_{aryl} represents a divalent aromatic cyclic group that optionally has a substituent. X₀₁ is a single bond or a divalent linking group. Each R² independently represents an organic group having a fluorine atom.]

Examples of a resist material include the following.

A resist material that includes a polymer having a repeating unit represented by Formula (a1) or (a2) below.

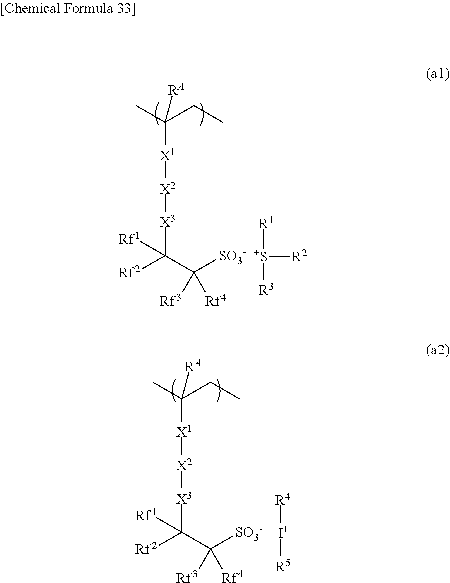

(In Formula (a1) and Formula (a2), R^{A} is a hydrogen atom or a methyl group. X¹ is a single bond or an ester group. X² is a linear, branched, or cyclic alkylene group with a carbon number of 1 to 12 or arylene group with a carbon number of 6 to 10, one or some of the methylene groups that constitute the alkylene group are optionally substituted with an ether group, an ester group, or a lactone ring-containing group; and at least one hydrogen atom contained in X² is substituted with a bromine atom. X³ is a single bond, an ether group, an ester group, or a linear, branched, or cyclic alkylene group with a carbon number of 1 to 12, and one or some of the methylene groups that constitute the alkylene group are optionally substituted with an ether group or an ester group. Rf¹ to Rf⁴ are each independently a hydrogen atom, a fluorine atom, or a trifluoromethyl group; and at least one of R¹ to Rf⁴ is a fluorine atom or a trifluoromethyl group. Rf¹ and Rf² may be bonded together to form a carbonyl group. R¹ to R⁵ are each independently a linear, branched, or cyclic alkyl group with a carbon number of 1 to 12, a linear, branched, or cyclic alkenyl group with a carbon number of 2 to 12, an alkynyl group with a carbon number of 2 to 12, an aryl group with a carbon number of 6 to 20, an aralkyl group with a carbon number of 7 to 12, or an aryloxyalkyl group with a carbon number of 7 to 12; part or all of hydrogen atoms of the groups is optionally substituted with a hydroxy group, a carboxy group, a halogen atom, an oxo group, a cyano group, an amide group, a nitro group, a sultone group, a sulfone group, or a sulfonium salt-containing group; and one or some of the methylene groups that constitute these groups is optionally substituted with an ether group, an ester group, a carbonyl group, a carbonate group, or a sulfonic acid ester group. R¹ and R² may be bonded to form a ring together with a sulfur atom to which R¹ and R² are bonded.)

A resist material that contains a base resin containing a polymer having a repeating unit represented by Formula (a) below.

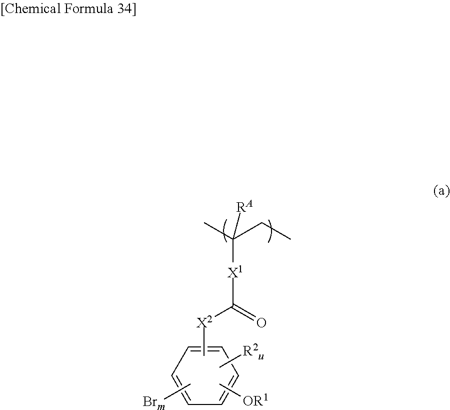

(In Formula (a), R^{A} is a hydrogen atom or a methyl group. R¹ is a hydrogen atom or an acid-labile group. R² is a linear, branched, or cyclic alkyl group with a carbon number of 1 to 6 or a halogen atom other than bromine. X¹ is a single bond, a phenylene group, or a linear, branched, or cyclic alkylene group with a carbon number of 1 to 12 that optionally includes an ester group or a lactone ring. X² is —O—, —O—CH₂—, or —NH—. m is an integer of 1 to 4. n is an integer of 0 to 3.)

Examples of the resist film include the following.

(i) A resist film that includes a base resin containing a repeating unit represented by Formula (a1) below and/or a repeating unit represented by Formula (a2) below, and a repeating unit that generates an acid bonded to the polymer main chain upon exposure.

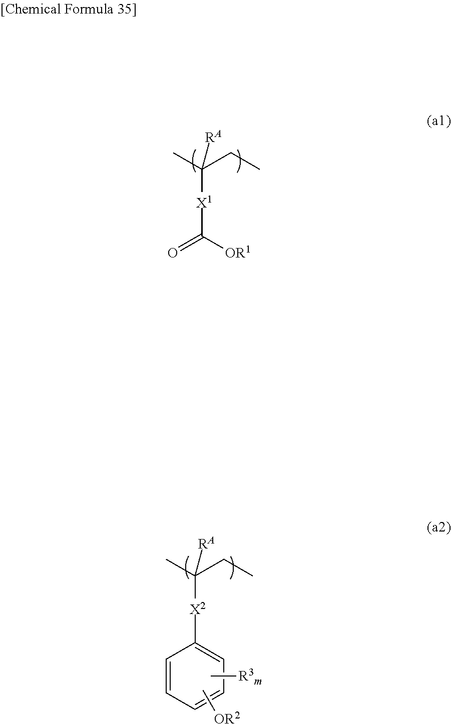

(In Formula (a1) and Formula (a2), each R^{A} is independently a hydrogen atom or a methyl group. R¹ and R² are each independently a tertiary alkyl group with a carbon number of 4 to 6. Each R³ is independently a fluorine atom or a methyl group. m is an integer of 0 to 4. X¹ is a single bond, a phenylene group, a naphthylene group, or a linking group with a carbon number of 1 to 12 that contains at least one selected from the group consisting of an ester bond, a lactone ring, a phenylene group, and a naphthylene group. X² is a single bond, an ester bond, or an amide bond.)

Examples of the coating solution include the following.

Examples of the metal-containing resist composition include coatings including a metal oxo-hydroxo network having an organic ligand through a metal-carbon bond and/or a metal-carboxylate bond.

An inorganic oxo/hydroxo-based composition.

A coating solution that includes: an organic solvent; a first organic metal composition, that is represented by formula R_{z}SnO_{(2-(z/2)-(x/2))}(OH)ₓ (wherein, 0<z≤2 and 0<(z+x)≤4) or formula R′ₙSnX₄₋ₙ (wherein, n=1 or 2), or is a mixture thereof in which R and R′ are each independently a hydrocarbyl group having 1 to 31 carbon atoms, and X is a ligand having a hydrolyzable bond to Sn or a combination of such ligands; and a hydrolyzable metal compound represented by formula MX′V (wherein, M is metal selected from Group 2 to Group 16 of the periodic table of elements, v=a number of 2 to 6, and X is a ligand having a hydrolyzable M-X bond or a combination of such ligands).

A coating solution that includes an organic solvent, and a first organic metal compound represented by formula RSnO_{(3/2-x/2)}(OH)ₓ (in the formula, 0<x<3), in which the solution includes about 0.0025 M to about 1.5 M of tin, R is an alkyl group or a cycloalkyl group having 3 to 31 carbon atoms, and the alkyl group or the cycloalkyl group is bonded to tin at a secondary or tertiary carbon atom.

An inorganic pattern-forming precursor aqueous solution that includes a mixture of water, a metal suboxide cation, a polyatomic inorganic anion, and a radiation-sensitive ligand including a peroxide group.

Exposure/irradiation is performed through a mask (reticle) for forming a predetermined pattern, and for example, i-ray, KrF excimer laser, ArF excimer laser, extreme ultraviolet ray (EUV), or electron beam (EB) is used, and the resist underlayer film-forming composition of the present application is preferably applied for electron beam (EB) irradiation and extreme ultraviolet ray (EUV) exposure. An alkali developer is used for development, and conditions are appropriately selected from development temperatures of 5° C. to 50° C. and development times of 10 seconds to 300 seconds. As the alkali developer, for example, aqueous solutions of alkalis such as inorganic alkalis including sodium hydroxide, potassium hydroxide, sodium carbonate, sodium silicate, sodium metasilicate, and aqueous ammonia, primary amines including ethylamine and n-propylamine, secondary amines including diethylamine and di-n-butylamine, tertiary amines including triethylamine and methyldiethylamine, alcohol amines including dimethylethanolamine and triethanolamine, quaternary ammonium salts including tetramethylammonium hydroxide, tetraethylammonium hydroxide, and choline, and cyclic amines including pyrrole and piperidine may be used.

In addition, alcohols such as isopropyl alcohol or a surfactant such as a nonionic surfactant may be added to the aqueous solutions of alkalis above in an appropriate amount for use. Of the developers, a quaternary ammonium salt is preferable, and tetramethylammonium hydroxide and choline are more preferable. In addition, a surfactant or the like may be added to the developers. A method that performs development with an organic solvent such as butyl acetate, instead of an alkali developer, and develops a portion where the alkali dissolution rate of the photoresist is not improved may be used. The substrate on which the resist is patterned may be manufactured through the above-mentioned steps.

Next, the resist underlayer film is dry-etched with the formed resist pattern as a mask. Here, when an inorganic film is formed on the surface of the semiconductor substrate used, the surface of the inorganic film is exposed, and when no inorganic film is formed on the semiconductor substrate used, the surface of the semiconductor substrate is exposed. Thereafter, a semiconductor device may be manufactured through the step of processing the substrate according to a known method (dry etching method or the like).

### EXAMPLES

Next, the present invention will be specifically described in conjunction with examples and the like, but the present invention is not limited to the examples.

The weight average molecular weight of the polymers in Synthesis Example 1 to Synthesis Example 4 and Comparative Synthesis Example 1 of the present specification below is a measurement result by gel permeation chromatography (hereinafter, simply referred to as GPC). In the measurement, a GPC apparatus manufactured by Tosoh Corporation is used, and the measurement conditions are as follows.
GPC Column: Shodex KF803L, Shodex KF802, Shodex KF801 [Registered Trademark] (Showa Denko K. K.)
Column temperature: 40° C.
Solvent: N,N-dimethylformamide (DMF)
Flow rate: 0.6 ml/minute
Standard sample: polystyrene (manufactured by Tosoh Corporation)

### Synthesis Example 1

As polymer 1, 6.00 g of monoallyl diglycidyl isocyanurate (manufactured by Shikoku Kasei Holdings Corporation), 3.36 g of diethylbarbital (manufactured by Hachidai Pharmaceutical Co., Ltd.), 0.72 g of citraconic anhydride (manufactured by Tokyo Chemical Industry Co., Ltd.), 0.19 g of 2,6-di-tert-butyl-p-cresol (manufactured by Tokyo Chemical Industry Co., Ltd.), and 0.55 g of tetrabutyl phosphonium bromide (manufactured by Tokyo Chemical Industry Co., Ltd.) were added to and dissolved in 32.44 g of propylene glycol monomethyl ether. After a reaction vessel was purged with nitrogen, reaction was carried out at 105° C. for 24 hours to obtain a polymer solution. GPC analysis showed that the obtained polymer had a weight average molecular weight of 4,900 in terms of standard polystyrene, and a dispersity of 3.0. The structure present in polymer 1 is shown in the following formula.

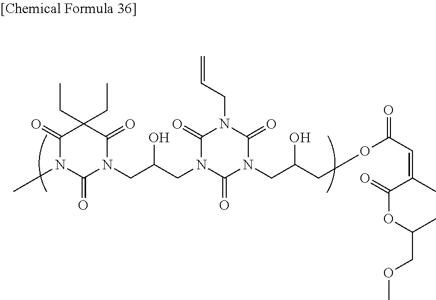

### Synthesis Example 2

As polymer 2, 6.00 g of monoallyl diglycidyl isocyanurate (manufactured by Shikoku Kasei Holdings Corporation), 3.36 g of diethylbarbital (manufactured by Hachidai Pharmaceutical Co., Ltd.), 0.63 g of maleic anhydride (manufactured by Tokyo Chemical Industry Co., Ltd.), 0.19 g of 2,6-di-tert-butyl-p-cresol (manufactured by Tokyo Chemical Industry Co., Ltd.), and 0.55 g of tetrabutyl phosphonium bromide (manufactured by Tokyo Chemical Industry Co., Ltd.) were added to and dissolved in 32.17 g of propylene glycol monomethyl ether. After a reaction vessel was purged with nitrogen, reaction was carried out at 105° C. for 24 hours to obtain a polymer solution. GPC analysis showed that the obtained polymer had a weight average molecular weight of 5,500 in terms of standard polystyrene, and a dispersity of 3.0. The structure present in polymer 2 is shown in the following formula.

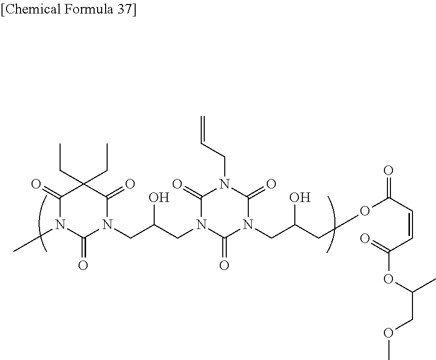

### Synthesis Example 3

As polymer 3, 6.00 g of monoallyl diglycidyl isocyanurate (manufactured by Shikoku Kasei Holdings Corporation), 5.59 g of bis(4-hydroxy-3,5-dimethylphenyl)sulfone (manufactured by Tokyo Chemical Industry Co., Ltd.), 0.72 g of citraconic anhydride (manufactured by Tokyo Chemical Industry Co., Ltd.), 0.19 g of 2,6-di-tert-butyl-p-cresol (manufactured by Tokyo Chemical Industry Co., Ltd.), and 0.55 g of tetrabutyl phosphonium bromide (manufactured by Tokyo Chemical Industry Co., Ltd.) were added to and dissolved in 39.13 g of propylene glycol monomethyl ether. After a reaction vessel was purged with nitrogen, reaction was carried out at 105° C. for 24 hours to obtain a polymer solution. GPC analysis showed that the obtained polymer had a weight average molecular weight of 7,900 in terms of standard polystyrene, and a dispersity of 3.2. The structure present in polymer 3 is shown in the following formula.

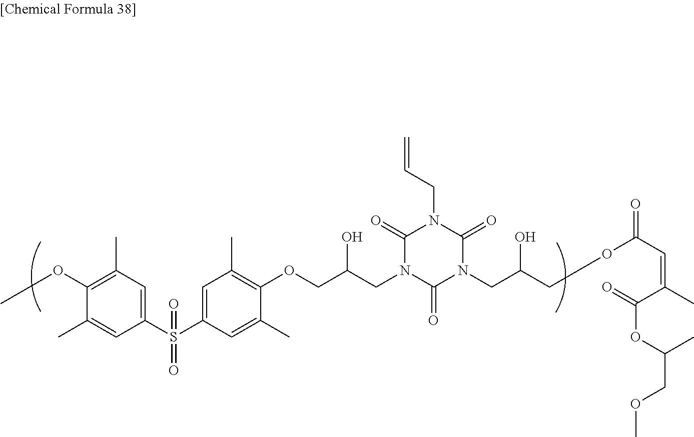

### Synthesis Example 4

As polymer 4, 6.00 g of monoallyl diglycidyl isocyanurate (manufactured by Shikoku Kasei Holdings Corporation), 5.59 g of bis(4-hydroxy-3,5-dimethylphenyl)sulfone (manufactured by Tokyo Chemical Industry Co., Ltd.), 0.63 g of maleic anhydride (manufactured by Tokyo Chemical Industry Co., Ltd.), 0.19 g of 2,6-di-tert-butyl-p-cresol (manufactured by Tokyo Chemical Industry Co., Ltd.), and 0.55 g of tetrabutyl phosphonium bromide (manufactured by Tokyo Chemical Industry Co., Ltd.) were added to and dissolved in 38.86 g of propylene glycol monomethyl ether. After a reaction vessel was purged with nitrogen, reaction was carried out at 105° C. for 24 hours to obtain a polymer solution. GPC analysis showed that the obtained polymer had a weight average molecular weight of 7,600 in terms of standard polystyrene, and a dispersity of 4.4. The structure present in polymer 4 is shown in the following formula.

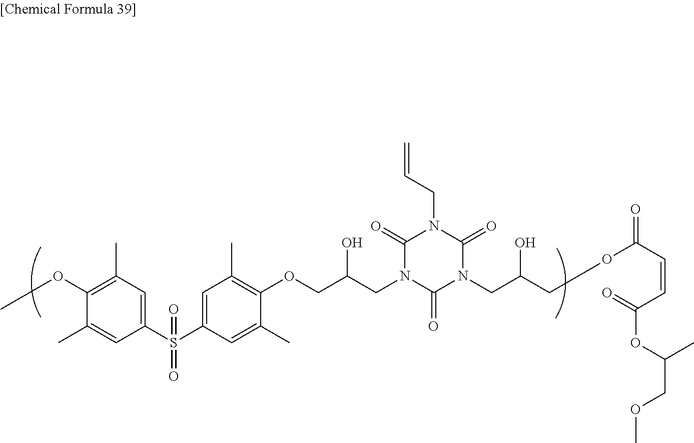

### Comparative Synthesis Example 1

As polymer 5, 10.00 g of N,N-diglycidyl-5,5-dimethylhydantoin (manufactured by Shikoku Kasei Holdings Corporation), 3.04 g of monoallyl isocyanuric acid (manufactured by Shikoku Kasei Holdings Corporation), and 0.63 g of 7-oxabicyclo[2.2.1]hepta-5-ene-2,3-dicarboxylic anhydride (manufactured by Tokyo Chemical Industry Co., Ltd.) were added to and dissolved in 14.41 g of propylene glycol monomethyl ether. After a reaction vessel was purged with nitrogen, reaction was carried out at 105° C. for 24 hours to obtain a polymer solution. GPC analysis showed that the obtained polymer had a weight average molecular weight of 3,200 in terms of standard polystyrene, and a dispersity of 1.6. The structure present in polymer 5 is shown in the following formula.

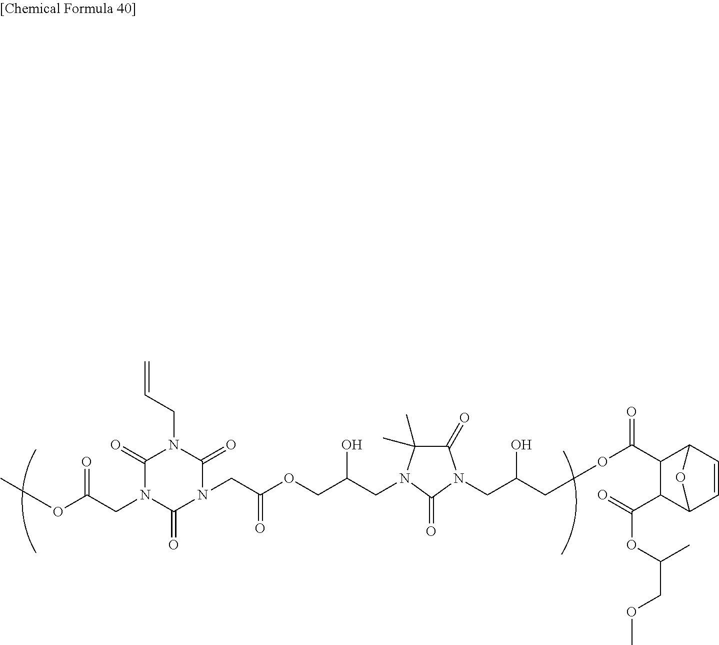

### (Preparation of Resist Underlayer Film)

### Examples, Comparative Example

Each of the polymers obtained in Synthesis Examples 1 to 4 and Comparative Synthesis Example 1 above, a crosslinking agent, a curing catalyst, a surfactant, and a solvent were mixed together at a ratio shown in Table 1, and the mixture was filtered through a 0.1 m fluororesin filter to prepare a solution of a composition for forming a resist underlayer film.

In Tables 1 and 2, tetramethoxymethylglycoluril (manufactured by Nihon Cytec Industries Inc.) is abbreviated as PL-LI, Imidazo[4,5-d]imidazole-2,5(1H,3H)-dione, tetrahydro-1,3,4,6-tetrakis[(2-methoxy-1-methylethoxy)methyl]- is abbreviated as PGME-PL, pyridinium-p-hydroxybenzene sulfonic acid is abbreviated as PyPSA, a surfactant is abbreviated as R-30N, propylene glycol monomethyl ether acetate is abbreviated as PGMEA, and propylene glycol monomethyl ether is abbreviated as PGME. The addition amounts are shown in parts by mass.

TABLE 1

| | | Crosslinking | Curing | | |
|---|---|---|---|---|---|
| | Polymer | Agent | Catalyst | Solvent | |
| Example 1 | Synthesis Example 1 | PGME-PL | PyPSA | PGME | PGMEA |
| (parts by mass) | 0.15 | 0.04 | 0.01 | 70 | 30 |
| Example 2 | Synthesis Example 2 | PGME-PL | PyPSA | PGME | PGMEA |
| (parts by mass) | 0.15 | 0.04 | 0.01 | 70 | 30 |
| Example 3 | Synthesis Example 3 | PGME-PL | PyPSA | PGME | PGMEA |
| (parts by mass) | 0.15 | 0.04 | 0.01 | 70 | 30 |
| Example 4 | Synthesis Example 4 | PGME-PL | PyPSA | PGME | PGMEA |
| (parts by mass) | 0.15 | 0.04 | 0.01 | 70 | 30 |

TABLE 2

| | | Crosslinking | Curing | | |
|---|---|---|---|---|---|
| | Polymer | Agent | Catalyst | Solvent | |
| Comparative | Comparative Synthesis | PL-LI | PyPSA | PGME | PGMEA |
| Example 1 | Example 1 | | | | |
| (parts by mass) | 0.15 | 0.04 | 0.01 | 70 | 30 |

(Test of Dissolution into Photoresist Solvent)

Each of the resist underlayer film-forming compositions of Examples 1 to 4 and Comparative Example 1 was applied on a silicon wafer using a spinner. The silicon wafer was baked on a hot plate at 205° C. for 60 seconds to obtain a film having a film thickness of 5 nm. The resist underlayer film was immersed in a solvent used for photoresist, specifically, a 70/30 mixed solution of propylene glycol monomethyl ether/propylene glycol monomethyl ether, the resist underlayer film was rated as good when a change in film thickness was not more than 1 Å, and was rated as defective when a change in film thickness was equal to or greater than 1 Å, and the results are shown in Table 3.

### (Film Formability Test)

Each of the resist underlayer film-forming compositions of Examples 1 to 4 and Comparative Example 1 was applied on a silicon wafer using a spinner. The silicon wafer was baked on a hot plate at 205° C. for 60 seconds to obtain a film having a film thickness of 5 nm. The surface roughness (Sa) of the resist underlayer film was measured using an atomic force microscope (AFM), the applicability was rated as good when the surface roughness was not more than 3 Å, and was rated as defective when the surface roughness was equal to or greater than 3 Å, and the results are shown in Table 3.

### [Table 3]

TABLE 3

| | Dissolution Test | Applicability |
|---|---|---|
| Example 1 | Good | Good |
| Example 2 | Good | Good |
| Example 3 | Good | Good |
| Example 4 | Good | Good |
| Comparative Example 1 | Good | Good |

### (Evaluation of Polymer Photocrosslinkability)

Each of the polymers of Synthesis Examples 1 to 4 and Comparative Synthesis Example 1 was applied on a silicon wafer using a spinner. The silicon wafer was baked on a hot plate at 205° C. for 60 seconds to obtain a polymer single film having a film thickness of 50 nm. Thereafter, the polymer single film was irradiated with light using a 172 nm light irradiation apparatus (manufactured by Ushio Inc.). The polymer single film was immersed in a solvent used for photoresist, specifically, a 70/30 mixed solution of propylene glycol monomethyl ether/propylene glycol monomethyl ether, a remaining film thickness was measured to calculate a film remaining rate, and the results are shown in Table 4.

### [Table 4]

TABLE 4

| | Film Remaining Rate |
|---|---|
| | After Irradiation with Light |
| Synthesis Example 1 | 69% |
| Synthesis Example 2 | 71% |
| Synthesis Example 3 | 73% |
| Synthesis Example 4 | 73% |
| Comparative Synthesis Example 1 | 65% |

### (Evaluation of Resist Patterning)

### [Test for Formation of Resist Pattern by Electron Beam Lithography Apparatus]

Each of the resist underlayer film-forming composition was applied on a silicon wafer using a spinner. The silicon wafer was baked on a hot plate at 205° C. for 60 seconds to obtain a resist underlayer film having a film thickness of 5 nm. A positive resist solution for EUV was applied on the resist underlayer film by spin coating and was heated at 130° C. for 60 seconds to form an EUV resist film. The resist film was subjected to exposure under predetermined conditions using an electron beam lithography apparatus (ELS-G130). After the exposure, the resist film was baked (PEB) at 90° C. for 60 seconds, was cooled to a room temperature on a cooling plate, and was subjected to puddle development for 30 seconds using a 2.38% aqueous solution of tetramethylammonium hydroxide (product name NMD-3, manufactured by Tokyo Ohka Kogyo Co., Ltd.) as a developer for photoresist. A resist pattern having a line size of 15 nm to 27 nm was formed. In the measurement of the length of the resist pattern, a scanning electron microscope (CG4100, manufactured by Hitachi High-Tech Corporation) was used.

The photoresist pattern obtained as such was checked whether 22 nm line and space (L/S) was formed. For all Examples 1 to 4 and Comparative Example 1, it was confirmed that 22 nm L/S pattern was formed. The amount of charge with which a 22 nm line/44 nm pitch (line and space (L/S=1/1) was formed was taken as an optimum irradiation energy, and the irradiation energy (μC/cm²) at the moment and the roughness (LWR) of the pattern line width are shown in Table 5.

### [Table 5]

TABLE 5

| | Irradiation Energy | LWR |
|---|---|---|
| | (mJ/cm²) | (nm) |
| Example 1 | 418 | 5.04 |
| Example 2 | 414 | 4.71 |
| Example 3 | 410 | 4.82 |
| Example 4 | 410 | 4.75 |
| Comparative Example 1 | 428 | 5.17 |

### INDUSTRIAL APPLICABILITY

The resist underlayer film-forming composition for lithography of the present invention is a composition, in which the polymer contained in the resist underlayer film-forming composition has an acyclic aliphatic hydrocarbon group at the terminal, the polymer being optionally interrupted by a group containing a heteroatom or being optionally substituted with a substituent, and it is a composition that contains such a polymer and an organic solvent, and preferably further contains a crosslinking agent and/or a compound for promoting a crosslinking reaction (curing catalyst). Attributable to such features, the resist underlayer film-forming composition for lithography of the present application enables forming a resist pattern having a satisfactory rectangular shape (without pattern collapse), as well as suppressing deterioration of LWR and improving sensitivity in forming the resist pattern.

1. A resist underlayer film-forming composition comprising: an organic solvent; and a polymer,
wherein the polymer has an acyclic aliphatic hydrocarbon group at a terminal, the acyclic aliphatic hydrocarbon group being optionally interrupted by a group containing a heteroatom or being optionally substituted with a substituent.

2. The resist underlayer film-forming composition according to claim 1,
wherein the acyclic aliphatic hydrocarbon group is an acyclic aliphatic hydrocarbon group having less than 12 carbon atoms.

3. The resist underlayer film-forming composition according to claim 1,
wherein the acyclic aliphatic hydrocarbon group contains at least one unsaturated carbon-carbon bond.

4. The resist underlayer film-forming composition according to claim 1,
wherein the group containing the heteroatom is at least one member selected from the group consisting of an ether group, a thioether group, a carbonyl group, a thiocarbonyl group, an ester group, a thioester group, a thionoester group, an amide group, a urea group, and an oxysulfonyl group.

5. The resist underlayer film-forming composition according to claim 1,
wherein the substituent is at least one member selected from the group consisting of a hydroxy group, a carboxy group, and a linear or branched alkyl, alkoxy, or acyloxy group having not more than 10 carbon atoms.

6. The resist underlayer film-forming composition according to claim 1,
wherein the polymer has at least one structural unit represented by Formula (3) in a main chain: 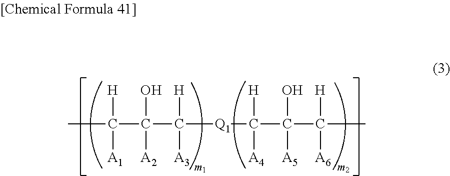
wherein, in Formula (3), A₁, A₂, A₃, A₄, A₅, and A₆ each independently represent a hydrogen atom, a methyl group, or an ethyl group; Q₁ represents a divalent organic group; and m₁ and m₂ each independently represent 0 or 1.

7. The resist underlayer film-forming composition according to claim 6,
wherein Q₁ in Formula (3) represents a divalent organic group represented by Formula (5): 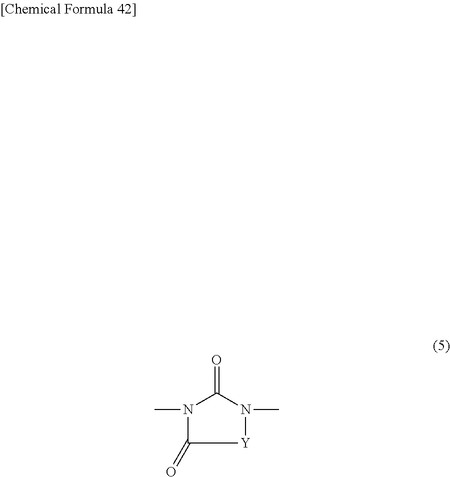
wherein, in the formula, Y represents a divalent group represented by Formula (6) or Formula (7): 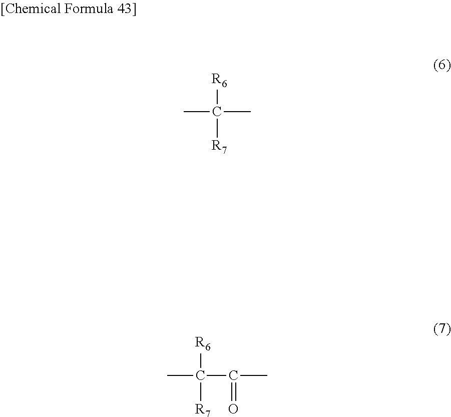
wherein, in the formulas, R₆ and R₇ each independently represent a hydrogen atom, an alkyl group having 1 to 6 carbon atoms, an alkenyl group having 3 to 6 carbon atoms, a benzyl group, or a phenyl group, the phenyl group being optionally substituted with at least one member selected from the group consisting of an alkyl group having 1 to 6 carbon atoms, a halogen atom, an alkoxy group having 1 to 6 carbon atoms, a nitro group, a cyano group, and an alkylthio group having 1 to 6 carbon atoms, or R₆ and R₇ are optionally bonded to each other to form a ring having 3 to 6 carbon atoms together with the carbon atom to which R₆ and R₇ are bonded.

8. The resist underlayer film-forming composition according to claim 1, further comprising a curing catalyst.

9. The resist underlayer film-forming composition according to claim 1, further comprising a crosslinking agent.

10. A resist underlayer film, which is a baked product of a coating film of the resist underlayer film-forming composition according to claim 1.

11. A method for manufacturing a patterned substrate, the method comprising the steps of: applying the resist underlayer film-forming composition according to claim 1 onto a semiconductor substrate and baking the resist underlayer film-forming composition to form a resist underlayer film; applying a resist on the resist underlayer film and baking the resist to form a resist film; exposing the semiconductor substrate coated with the resist underlayer film and the resist; and developing the exposed resist film and performing patterning.

12. A method for manufacturing a semiconductor device, the method comprising the steps of:
forming a resist underlayer film of the resist underlayer film-forming composition according to claim 1 on a semiconductor substrate;
forming a resist film on the resist underlayer film;
forming a resist pattern by irradiation of the resist film with a light or electron beam and development that follows;
forming a patterned resist underlayer film by etching the resist underlayer film via the formed resist pattern; and
processing the semiconductor substrate by the patterned resist underlayer film.
